(19) United States
(12) Patent Application Publication
(10) Pub. No.: US 2026/0284834 A1
(43) Pub. Date: Sep. 24, 2026

(54) DECONTAMINATION MATERIAL AND MANUFACTURING METHOD THEREOF, AND METHOD OF CLEANING PROBE

(71) Applicant: Alliance Material Co., Ltd., Hsinchu County (TW)

(72) Inventors: Yu-Hsuen Lee, Hsinchu County (TW); Ting-Wei Lin, Hsinchu County (TW); Ching-Wen Hsu, Hsinchu County (TW); Chao-Hsuan Yang, Hsinchu County (TW); Chun Fa Chen, Hsinchu County (TW); Hsueh Chung Wu, Hsinchu County (TW)

(73) Assignee: Alliance Material Co., Ltd., Hsinchu County (TW)

(21) Appl. No.: 19/688,406

(22) Filed: May 26, 2026

Related U.S. Application Data
(63) Continuation-in-part of application No. 18/506,139, filed on Nov. 10, 2023, now Pat. No. 12,674,819.
Application No. 18/506,139 is a continuation-in-part of application No. 17/691,129, filed on Mar. 10, 2022, now Pat. No. 11,865,588.
Application No. 17/691,129 is a continuation-in-part of application No. 17/095,747, filed on Nov. 12, 2020, now abandoned.
(63) Continuation-in-part of application No. 19/363,655, filed on Oct. 21, 2025.
(60) Provisional application No. 62/933,990, filed on Nov. 12, 2019.

(30) Foreign Application Priority Data
Mar. 2, 2020 (TW) 109106766
Oct. 22, 2020 (TW) 109136656
Sep. 23, 2023 (TW) 112136486
Sep. 23, 2025 (TW) 114136540
Apr. 17, 2026 (TW) 115115058

(51) Int. Cl. B24D 3/02; B24D 13/14; C11D 17/00

(52) U.S. Cl. CPC B24D 3/02; B24D 13/147; C11D 17/0039

(57) ABSTRACT

A decontamination material including a support layer and a cleaning layer is provided. The cleaning layer is disposed on the support layer. The cleaning layer is made of resin, a plurality of cleaning particles dispersed in the resin, a plurality of abrasive particles dispersed in the resin, and a plurality of hollow polymer microspheres dispersed in the resin. The cleaning particles have a Mohs hardness of less than 7. The abrasive particles have a Mohs hardness of greater than or equal to 7. A manufacturing method of a decontamination material and a method of cleaning a probe are also provided.

### CROSS-REFERENCE TO RELATED APPLICATION

This application is a continuation-in-part application of U.S. patent application Ser. No. 18/506,139, filed on Nov. 10, 2023, now allowed, and U.S. patent application Ser. No. 19/363,655, filed on Oct. 21, 2025, now pending. The U.S. patent application Ser. No. 19/363,655 claims the priority benefit of Taiwan application serial no. 114136540, filed on Sep. 23, 2025. The U.S. patent application Ser. No. 18/506,139 is a continuation-in-part application of U.S. patent application Ser. No. 17/691,129, filed on Mar. 10, 2022, now U.S. Pat. No. 11,865,588 B2. The U.S. patent application Ser. No. 18/506,139 also claims the priority benefit of Taiwan application serial no. 112136486, filed on Sep. 23, 2023. The U.S. patent application Ser. No. 17/691,129 is a continuation-in-part application of U.S. patent application Ser. No. 17/095,747, filed on Nov. 12, 2020, now abandoned, which claims the priority benefits of U.S. provisional application Ser. No. 62/933,990, filed on Nov. 12, 2019, Taiwan application serial no. 109106766, filed on Mar. 2, 2020 and Taiwan application serial no. 109136656, filed on Oct. 22, 2020. This application also claims the priority benefit of Taiwan application serial no. 115115058, filed on Apr. 17, 2026. The entirety of each of the above-mentioned patent applications is hereby incorporated by reference herein and made a part of this specification.

### BACKGROUND

### Technical Field

The present disclosure relates to a decontamination material and a manufacturing method thereof, and particularly relates to a decontamination material that may be used for probe cleaning and a manufacturing method thereof.

### Description of Related Art

In high-precision processes such as semiconductor wafer Chip Probing (CP) or Final Test (FT), probes (e.g., vertical probes, cantilever probes, or crown-type probes) must repeatedly contact conductive terminals (e.g., pads or solder balls) on a wafer under test within an extremely short period of time to perform electrical measurements. During these high-frequency and high-pressure contact (Touch Down) processes, substances on the surface of the conductive terminals (e.g., solder, gold, aluminum, copper, and oxides thereof) are highly susceptible to being stripped off by friction, and subsequently adhere to and gradually accumulate on the probe tips. When these fine contaminants or metal oxide layers accumulate to a certain extent, they will cause the contact resistance (CRES) between the probes and the wafer to become unstable or abnormally elevated, thereby inducing yield rate misjudgment (Yield loss), which seriously affects the accuracy and reliability of semiconductor testing.

Accordingly, there is an urgent need in the art of high-precision semiconductor testing for a decontamination material that achieves an optimal balance among multiple stringent requirements, including “maintaining strong cutting and decontamination capability,” “providing ultimate cushioning to achieve low probe wear,” and “ensuring high-strength structural stability to prevent secondary contamination.”

### SUMMARY

The present disclosure provides a decontamination material and a manufacturing method thereof, wherein the decontamination material may be suitable for cleaning probes or removing stains on the probes.

A decontamination material of the present disclosure includes a support layer and a cleaning layer. The cleaning layer is disposed on the support layer. The material of the cleaning layer includes a resin, a plurality of cleaning particles dispersed in the resin, a plurality of abrasive particles dispersed in the resin, and a plurality of hollow polymer microspheres dispersed in the resin. The Mohs hardness of the cleaning particles is less than 7. The Mohs hardness of the abrasive particles is greater than or equal to 7.

A manufacturing method of the decontamination material of the present disclosure includes: providing a support layer; mixing a resin, a plurality of cleaning particles, a plurality of abrasive particles, and a plurality of hollow polymer microspheres to form a coating liquid, wherein the Mohs hardness of the cleaning particles is less than 7, and the Mohs hardness of the abrasive particles is greater than or equal to 7; applying the coating liquid onto the support layer; and curing the coating liquid to form a cleaning layer.

A method of cleaning a probe of the present disclosure includes: providing the aforementioned decontamination material; applying pressure to cause a probe under test to penetrate the cleaning layer of the decontamination material, wherein the hollow polymer microspheres undergo elastic deformation to absorb an impact force during penetration of the probe under test; and separating the probe under test from the cleaning layer to remove a substance therefrom, wherein at least a portion of the removed substance is encapsulated within the resin.

In view of the foregoing, since the resin encapsulates the cleaning particles, the abrasive particles, and the hollow polymer microspheres and fixes them on the support layer, a cleaning layer having an appropriate cleaning function is formed. Accordingly, the decontamination material is suitable for cleaning probes or removing stains therefrom.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a partial cross-sectional schematic view of a decontamination material according to an embodiment of the present disclosure.

FIG. 2A to FIG. 2F are schematic views of a cleaning method of a probe according to an embodiment of the present disclosure.

FIG. 3A to FIG. 3C are partial cross-sectional enlarged schematic views of a usage of a decontamination material according to an embodiment of the present disclosure.

FIG. 4 is a partial cross-sectional enlarged view of the decontamination material of [Example 1] after fabrication and before use.

FIG. 5A is a partial surface enlarged view of the decontamination material of [Example 2-1] after fabrication and before use.

FIG. 5B is a partial surface enlarged view of the decontamination material of [Example 2-3] after fabrication and before use.

FIG. 5C is a partial surface enlarged view of the decontamination material of [Example 2-4] after fabrication and before use.

FIG. 5D is a partial surface enlarged view of the decontamination material of [Example 2-5] after fabrication and before use.

FIG. 6A to FIG. 6B are test photographs of compression ratio tests performed on the cleaning layers of [Example 3-1], [Example 3-2], [Example 3-3], [Example 3-4], and [Example 3-5].

### DESCRIPTION OF THE EMBODIMENTS

The directional terms used herein (e.g., upper, lower, right, left, top, bottom) are used only with reference to the illustrated drawings and are not intended to imply absolute orientation.

The non-limiting terms used in the specification (e.g., about, essentially, approximately, may, might, could) may be a representation of an embodiment, and the content or values represented thereby may be within an acceptable deviation range for a person of ordinary skill in the art. For example, the represented values may include the stated values and deviation values within an acceptable deviation range for a person of ordinary skill in the art. The aforementioned deviation values may be one or more standard deviations in the manufacturing process or measurement process, or calculation errors generated by other factors such as the number of digits adopted, rounding, or Error Propagation in the calculation or conversion process.

To mitigate or resolve the issue of probe contamination and maintain the stable operation of test equipment, it is conventional in the art to utilize dedicated decontamination materials (e.g., needle-cleaning sandpaper or cleaning pads) periodically to perform physical scraping and cleaning on the probes. The cleaning layer of some types of decontamination materials mostly adopts high hardness inorganic abrasives (e.g., silicon carbide particles or corundum) dispersed in a resin matrix. Although such high hardness abrasive particles possess excellent cutting and decontamination capability, capable of forcefully stripping stubborn oxides on the probe surface, their excessively high rigidity and friction often cause severe physical wear on the probe tip at the instant the probe penetrates at high speed, significantly shortening the service life of the expensive probes and probe cards.

In order to reduce the wear of the probes, some advanced decontamination materials attempt to mix and add low hardness solid organic particles into the cleaning layer, with the expectation of providing partial cushioning by reducing the overall effective hardness of the cleaning layer, while also assisting in loosening and adsorbing fine contaminants. However, although solid cleaning particles are softer than high hardness abrasive particles, due to the lack of free volume and air chamber space inside for compressive yielding, the elastic stroke and shock absorption effect they could provide still have limitations when facing the more stringent overdrive stress and instantaneous impact in modern advanced packaging and testing processes. If the resin matrix is simply softened to further increase cushioning, it will result in insufficient crosslink density and cohesion of the cleaning layer, causing the cleaning layer to be prone to structural disintegration, particle detachment (debris shedding), or colloidal adhesion when the probe penetrates, thereby triggering a more troublesome secondary pollution problem. Furthermore, conventional cleaning materials often exhibit a linear elastic response that fails to provide sufficient localized compliance during high-speed, high-pressure overdrive cycles. Consequently, the impact energy might be directly transmitted to the fragile probe tips, leading to cumulative fatigue and irreversible deformation. There remains a significant technological void for a cleaning architecture capable of providing a non-linear, energy-dissipative buffering mechanism while simultaneously ensuring high-efficiency contaminant removal.

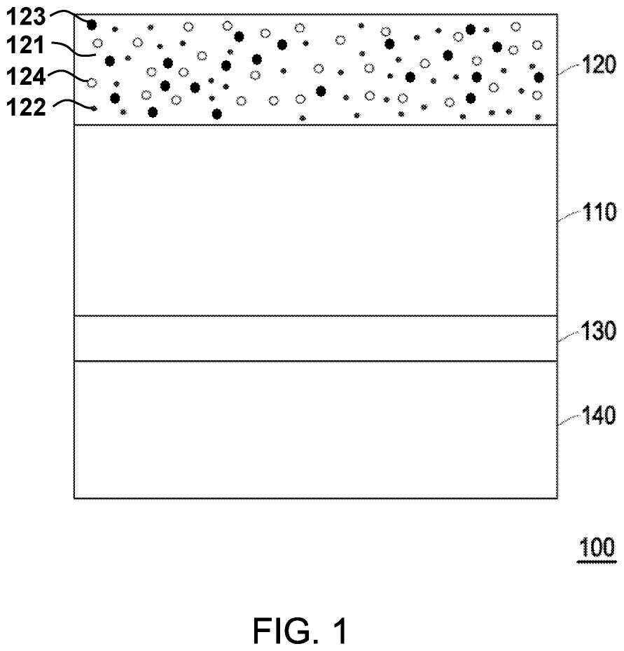

FIG. 1 is a partial cross-sectional schematic view of a decontamination material according to an embodiment of the present disclosure.

Referring to FIG. 1, the decontamination material 100 may include a stacked structure, which may include a support layer 110 and a cleaning layer 120. In an embodiment, the support layer 110 may serve as the supporting main body structure of the decontamination material 100, and its function is to provide sufficient mechanical strength and stability. The cleaning layer 120 may be stacked on the support layer 110. The cleaning layer 120 may be regarded as a single film layer. In other words, the material included in the cleaning layer 120 is substantially uniformly distributed.

In an embodiment, the decontamination material 100 may optionally further include an adhesive layer 130. The adhesive layer 130 and the cleaning layer 120 are respectively located on two opposite sides of the support layer 110. For example, the adhesive layer 130 is located on one side of the support layer 110 (as shown at the lower side in the drawing), and its primary function is to provide stable adhesion so that the decontamination material 100 may be fixed on a work surface or a surface of a corresponding device.

In an embodiment, the decontamination material 100 may optionally further include a release layer 140, which covers a side of the adhesive layer 130 away from the support layer 110, so as to protect the adhesive layer 130 when not in use, reducing or avoiding contamination by dust or loss of adhesiveness.

### <Support Layer>

The support layer 110 may be regarded as the main body structure of the decontamination material 100. The support layer 110 is configured to provide sufficient mechanical strength, dimensional stability, or chemical stability to support the film layers thereon. In an embodiment, the support layer 110 may also be referred to as a substrate. In order to balance structural support, processability, and flexibility in actual applications, the thickness of the support layer 110 may be appropriately selected. In an embodiment, the thickness of the support layer 110 could be approximately in a range from 50 micrometers (μm) to approximately 8000 micrometers. For example, the thickness of the support layer 110 may be substantially 100 micrometers.

The thickness range of the support layer 110 is selected based on corresponding technical considerations. If the thickness of the support layer 110 is less than 50 micrometers, the rigidity and support it provides may be insufficient, and wrinkling or deformation may easily occur during operation or transfer; moreover, during the probe cleaning process, the thinner support layer 110 may be easily damaged by the downward external force of the probe, and may even cause the probe to pierce through the decontamination material 100 and damage the stage below. On the other hand, if the thickness of the support layer 110 is greater than 8000 micrometers, it may cause the overall thickness of the decontamination material 100 to become excessively thick, which not only leads to increased material costs, but may also exceed the specification limits of semiconductor-related equipment (e.g., transfer equipment including trays or transfer arms; such as test equipment including test benches), or may affect the compliance of bonding due to excessive rigidity, thereby reducing the applicability of the product.

In order to achieve the required physical properties and adapt to different test environments (e.g., high and low temperature test environments), the material of the support layer 110 may be selected from materials with good temperature resistance and chemical resistance. In an embodiment, the material of the support layer 110 may include polyethylene terephthalate (PET), polyimide (PI), polyether ether ketone (PEEK), polyetherimide (PEI), polyamide (PA), polyethersulfone (PES), polyethylene naphthalate (PEN), wafers (e.g., silicon wafers), glass, metal plates, glass fiber boards (e.g., FR4), ceramic plates, or a stack or combination of the above materials. For example, if the decontamination material 100 is applied in a high temperature test environment, polyimide, polyether ether ketone, ceramics, or wafers with better heat resistance may be selected as the material of the support layer 110.

### <Adhesive Layer>

The adhesive layer 130 may be disposed below the support layer 110 (at the lower side in FIG. 1). One function of the adhesive layer 130 is to provide stable adhesion so as to temporarily or permanently fix the decontamination material 100 on a surface of an appropriate object (e.g., a work surface including a stage; or an object including a substrate simulating a chip or a dummy chip), ensuring that the decontamination material 100 does not undergo unexpected displacement or sliding during the probe cleaning operation.

In an embodiment, the thickness of the adhesive layer 130 may be appropriately selected. For example, the thickness of the adhesive layer 130 could be in a range from 10 micrometers (μm) to 50 micrometers. For example, the thickness of the adhesive layer 130 may be substantially 25 micrometers. The setting of this thickness range has technical considerations: if the thickness of the adhesive layer 130 is less than 10 micrometers, it may result in insufficient coating amount of the adhesive, failing to provide sufficient surface wetting force and grip, causing the decontamination material 100 to detach when subjected to lateral forces from probe scraping; on the other hand, if the thickness of the adhesive layer 130 is greater than 50 micrometers, in addition to increasing material costs, the excessively thick adhesive layer may cause an oozing phenomenon when subjected to pressure, contaminating the equipment stage, or affecting the overall flatness (Total Thickness Variation, TTV) of the decontamination material 100 due to uneven adhesive layer thickness.

In order to adapt to different operating environments (e.g., high temperature test environments or general room temperature environments), the type of material of the adhesive layer 130 may be appropriately selected. In an embodiment, the material of the adhesive layer 130 may include acrylic resin, silicone resin, rubber-based resin, polyurethane resin, or a combination of the above.

For example, if cost and adhesion under general environments are considered, acrylic resin may be selected, which may be copolymerized from monomers such as butyl acrylate and isooctyl acrylate, with isocyanate or epoxy resin added as a crosslinking agent. For example, if applied in a semiconductor high temperature test process, silicone resin with better heat resistance may be selected, such as addition-type silicone resin or peroxide-type silicone resin, in order to reduce or avoid adhesive residue at high temperatures.

The adhesion force of the adhesive layer 130 may be appropriately selected, for example, controlled in a range from 100 gf/25 mm to 2000 gf/25 mm (tested according to the JIS Z 0237 standard). This range ensures that the decontamination material 100 could be firmly bonded, and could be easily peeled off during replacement without leaving adhesive residue on the corresponding object.

In an embodiment, regarding the formation method of the adhesive layer 130, either a direct coating method or a transfer coating method may be adopted according to process requirements. In the direct coating method, a liquid adhesive composition is directly coated on the surface of the support layer 110, and a film is formed through drying or curing (e.g., thermal curing or UV curing). In the transfer coating method, the adhesive is first coated on a release carrier, and after drying or curing, it is transferred and laminated onto the support layer 110 by a laminating roller.

The coating technology used to form the adhesive layer 130 may be appropriately selected to ensure uniformity of thickness. Applicable coating methods include, but are not limited to: slot-die coating, micro-gravure coating, comma coating, roll coating, or screen printing. By means of the appropriate coating technology described above, the thickness variation of the adhesive layer 130 may be controlled within a small range (e.g., within ±2 micrometers), so as to meet the requirements of precision testing.

### <Release Layer>

In an embodiment, if the decontamination material 100 is provided with the adhesive layer 130, a release layer 140 may be selectively further disposed. The release layer 140 covers a side of the adhesive layer 130 facing away from the support layer 110 (at the lower side in FIG. 1). One function of the release layer 140 is to protect the surface of the adhesive layer 130 before the decontamination material 100 is used or attached to an appropriate object, so as to reduce or avoid contamination caused by contact with dust in the air, or to avoid loss of adhesiveness or unnecessary adhesion caused by accidental contact. During use, the user may easily peel off the release layer 140 to expose the adhesive layer 130 for attachment and fixation.

The material of the release layer 140 may be appropriately selected. In an embodiment, the release layer 140 may include a polymer film or paper. The material of the polymer film includes, for example, polyethylene terephthalate (PET), polypropylene (PP), polyethylene (PE), or polystyrene (PS). The material of the paper includes, for example, glassine paper, kraft paper, or poly-coated paper. In order to achieve an appropriate release effect (e.g., easy separation from the adhesive layer 130), the surface of the release layer 140 in contact with the adhesive layer 130 may be subjected to a release treatment, such as coating with a release agent. The type of release agent may be appropriately selected according to the material properties of the adhesive layer 130. For example, if the adhesive layer 130 is an acrylic-based or rubber-based adhesive, a silicone-based release agent may be selected; if the adhesive layer 130 is a silicone-based adhesive, a fluorine-based release agent or a long-chain alkyl-based release agent (non-silicone release agent) may be selected, so as to ensure an appropriate peel force between the two.

The physical properties of the release layer 140 (e.g., thickness and release force) may be appropriately selected to balance both protection and operational convenience. In an embodiment, the thickness of the release layer 140 could be in a range from 25 micrometers to 175 micrometers. The setting of this thickness range has technical considerations: if the thickness of the release layer 140 is less than 25 micrometers, the film rigidity is insufficient, and damage or curling may easily occur during the peeling process, causing operational inconvenience; if the thickness of the release layer 140 is greater than 175 micrometers, unnecessary material costs and overall thickness may be increased, and it may be more difficult to store by rolling.

In addition, the release force of the release layer 140 may also be appropriately selected. The release force of the release layer 140 on the adhesive layer 130 is less than the adhesion force of the adhesive layer 130 on the support layer 110. In an embodiment, the release force of the release layer 140 on the adhesive layer 130 could be in a range from 2 gf/25 mm to 200 gf/25 mm. If the release force is less than 2 gf/25 mm, the release layer 140 may undergo pre-peeling during cutting, transportation, or storage due to excessively low adhesion, causing the adhesive layer 130 to be exposed and rendered ineffective; if the release force is greater than 200 gf/25 mm, the release layer 140 and the adhesive layer 130 are bonded too tightly (heavy release), and the user needs to apply a greater force when peeling off, which may cause the decontamination material 100 to wrinkle or deform, affecting subsequent flatness.

Regarding the formation method and attachment method of the release layer 140, a variety of process means may be adopted. In an embodiment, a release agent may be coated on an appropriate substrate by a coating method (e.g., gravure coating, blade coating, Mayer Rod coating), and the release layer 140 is formed through thermal curing or UV curing; subsequently, a lamination technology may be used to laminate the pre-prepared release layer 140 onto the support layer 110 that has been coated with the adhesive layer 130. In another embodiment (transfer coating method), the adhesive layer 130 may also be first coated on the release surface of the release layer 140, and after the adhesive layer 130 is dried or cured, it is then transferred and laminated onto the support layer 110.

### <Cleaning Layer>

Please refer to FIG. 1, the cleaning layer 120 is disposed on the support layer 110 (at the upper side in FIG. 1). The cleaning layer 120 is the primary functional layer for performing cleaning operations in an embodiment. In terms of structural composition, the cleaning layer 120 uses the resin 121 as a matrix or binder, and is mixed with a plurality of cleaning particles 122, a plurality of abrasive particles 123, and a plurality of hollow polymer microspheres 124 dispersed therein. The resin 121 fixes the cleaning particles 122, the abrasive particles 123, and the hollow polymer microspheres 124 onto the support layer 110, forming a film layer with an appropriate cleaning function.

The thickness of the cleaning layer 120 may be appropriately selected to match the tip length of the probe to be cleaned or the overdrive stroke of the equipment, or to match the composition of the cleaning layer 120. In an embodiment, the thickness of the cleaning layer 120 could be in a range from 100 micrometers to 400 micrometers. For example, the thickness of the cleaning layer 120 may be substantially 250 micrometers. The setting of this thickness range has technical considerations: if the thickness of the cleaning layer 120 is less than 100 micrometers, when the probe is pressed down for cleaning, the probe tip may easily pierce through the cleaning layer 120 and contact the support layer 110 below, resulting in poor cleaning performance or damage to the probe tip; if the thickness of the cleaning layer 120 is greater than 400 micrometers, the overall film thickness may be too thick, making it difficult to control thickness uniformity during the coating process, or causing unnecessary residual stress during the curing process. The cleaning particles, the abrasive particles, and the hollow polymer microspheres may function as a synergistic triad within the resin matrix. Specifically, while the abrasive particles provide the requisite mechanical scuffing to disrupt debris, the cleaning particles act as high-surface-area adsorbents to capture and sequester the loosened debris. Concurrently, the hollow polymer microspheres modulate the macroscopic stiffness of the cleaning layer, ensuring that the abrasive engagement is localized to the surface contaminants without inducing excessive frictional stress on the down-pressed probe.

### <Cleaning Particles>

The cleaning particles 122 (also referred to as first particles or soft particles) are distributed in the resin 121, and coexist in mixture with the abrasive particles 123 and the hollow polymer microspheres 124. The cleaning particles 122 are used to provide a buffering effect during the cleaning process and an adsorption effect on fine contaminants. To mitigate or prevent excessive wear on the probe surface during the cleaning process, the hardness of the cleaning particles 122 may be appropriately selected. For example, the Mohs hardness of the cleaning particles 122 is less than 7. Since the hardness of the cleaning particles 122 is relatively low, when the probe penetrates into the cleaning layer 120, the cleaning particles 122 may form an elastic encapsulation or soft contact around the probe, which helps to carry away dirt with weaker adhesion, while absorbing part of the impact force when the probe contacts the cleaning layer 120.

The chemical composition and surface properties of the cleaning particles 122 may have an influence on the compatibility with the resin 121 and the adsorption force on contaminants. In an embodiment, the type of the cleaning particles 122 may include compounds or glass containing appropriate organic functional groups. The appropriate organic functional groups include, for example: alkenyl, ether, amide, amino, carboxyl, ester, hydroxyl, silyl, alkoxy, alkoxysilyl, or a combination thereof.

For example, the cleaning particles 122 may be organic polymer particles that inherently contain the aforementioned functional groups, such as cross-linked poly(methyl methacrylate) (PMMA) particles or polystyrene (PS) particles. Alternatively, the cleaning particles 122 may be surface-modified inorganic particles. For example, glass beads may be surface-modified in an appropriate manner (e.g., performing a surface grafting reaction using a silane coupling agent) so that the surface thereof has corresponding alkenyl, ether, amide, amino, carboxyl, ester, hydroxyl, silyl, alkoxy, or alkoxysilyl groups. Through the presence of the aforementioned functional groups, the interfacial bonding force between the cleaning particles 122 and the resin 121 may be enhanced, preventing or reducing particle fall-out during operation.

The morphology of the cleaning particles 122 may be appropriately selected, for example, spherical or polygonal (irregular). The particle size distribution (for example, D50 particle size) of the cleaning particles 122 could be in a range from 0.05 micrometers to 30 micrometers. The selection of this particle size range may be to ensure that the particles could effectively enter the fine grooves on the probe surface for cleaning; if the particle size is too large, the contact area is reduced; if the particle size is too small, it is difficult to achieve the effect of physical wiping.

In an embodiment, in order to make the surface of the cleaning particles 122 carry corresponding functional groups (e.g., alkenyl, ether, amide, amino, carboxyl, ester, hydroxyl, silyl, alkoxy, or alkoxysilyl), surface modification treatment may be performed on the cleaning particles 122. The method of modification may be appropriately selected according to the original material (inorganic or organic) of the cleaning particles 122. In addition, these functional groups directly participate in the cross-linking reaction during the curing process of the resin 121 (for example, during the hydrosilylation reaction), so that appropriate bonding (e.g., covalent bond or Van der Waals force) is formed between the particle surface and the resin network structure. This interfacial chemical anchoring technology mitigates the risk of interfacial delamination, which frequently occurs in conventional decontamination materials under repeated thermal cycling due to a coefficient of thermal expansion (CTE) mismatch between the particles and the matrix (e.g., the resin).

In an embodiment, when the original material of the cleaning particles 122 is selected from inorganic materials such as glass beads, since the surface thereof is usually rich in hydroxyl groups (—OH), it is suitable to use a silane coupling agent for surface grafting modification. For example, the general structural formula of a silane coupling agent is Y—R—Si—X₃₋ₙHₙ. Wherein, n is 0, 1, or 2; X is a hydrolyzable group (e.g., methoxy, ethoxy), which after hydrolysis could undergo a condensation reaction with the hydroxyl groups on the surface of the inorganic particles to form a stable silicon-oxygen bond (Si—O-M, where M is the atom on the particle surface); Y is an organic functional group, for example, the aforementioned target groups such as alkenyl and amino; R is a linking group.

In order to introduce corresponding functional groups, the type of silane coupling agent may be appropriately selected. For example, if alkenyl is to be introduced, vinyltrimethoxysilane or vinyltriethoxysilane may be selected. For example, if amino is to be introduced, 3-aminopropyltriethoxysilane (APTES) or N-2-(aminoethyl)-3-aminopropyltrimethoxysilane may be selected. For example, if epoxy (which may be regarded as a precursor or form of an ether group) is to be introduced, 3-glycidoxypropyltrimethoxysilane may be selected. For example, if an ester group (e.g., methacryloxy) is to be introduced, 3-methacryloxypropyltrimethoxysilane may be selected. For example, if carboxyl or hydroxyl is to be introduced, a silane coupling agent containing an anhydride group or an epoxy group may first be used to modify the particle surface, and then the conversion may be obtained through a hydrolytic ring-opening reaction or a secondary reaction with polyols/polyacids.

In an embodiment, regarding the exemplary implementation method of surface modification, a wet method or a dry method may be adopted.

In the aforementioned wet method, the raw material particles used for making the cleaning particles 122 may first be dispersed in a solvent (e.g., water, ethanol, or a mixture thereof) to form a slurry. Next, an appropriate amount (for example: 0.5 wt % to 5 wt % relative to the weight of the particles) of a silane coupling agent is added, and the pH value is adjusted to promote hydrolysis. Subsequently, the reaction is stirred at an appropriate temperature (e.g., room temperature to 80° C.) for a certain period of time (e.g., 1 hour to 4 hours) to allow the coupling agent to be sufficiently grafted onto the particle surface. Finally, through filtration, washing, and drying procedures (e.g., drying at 100° C. to 120° C.), cleaning particles 122 with corresponding functional groups on the surface may be obtained.

In the aforementioned dry method, the raw material particles used for making the cleaning particles 122 may first be placed in a high-speed mixer (e.g., a Henschel Mixer), and under the condition of high-speed stirring, the silane coupling agent (or its diluent) is uniformly sprayed onto the particle surface by atomized spraying. Next, the mixture is heated to an appropriate temperature (e.g., 80° C. to 130° C.) and maintained for a period of time to complete the surface condensation reaction. The dry method is suitable for mass production and does not require a subsequent solvent removal step.

When the cleaning particles 122 are organic polymer particles, the formation method may be directly prepared through copolymerization of monomers. For example, suspension polymerization or emulsion polymerization may be adopted. During the polymerization process, in addition to the main structural monomers (e.g., methyl methacrylate, styrene), monomers with functional groups are also added. For example, if carboxyl groups are to be present on the particle surface, acrylic acid or methacrylic acid may be added for copolymerization. For example, if hydroxyl groups are to be present, 2-hydroxyethyl methacrylate (HEMA) may be added. For example, if amide groups are to be present, acrylamide may be added. For example, if alkoxysilyl groups are to be present, 3-methacryloxypropyltrimethoxysilane may be added as a comonomer. By controlling the polymerization conditions and monomer ratios, organic cleaning particles 122 with a particle size ranging from 0.05 micrometers to 30 micrometers and with appropriate reactivity on the surface may be prepared. Cleaning particles 122 of an appropriate particle size range may be selected by appropriate means (e.g., with a sieve). The particle size of the cleaning particles 122 may be selected according to the thickness of the corresponding cleaning layer 120; for example: the maximum particle size of the cleaning particles 122 is less than the thickness of the cleaning layer 120; for example: the maximum particle size of the cleaning particles 122 is less than or approximately equal to 20%, 10%, 1%, 0.5%, 0.1%, 0.05%, or 0.02% of the thickness of the cleaning layer 120.

In addition, in terms of the availability of commercially available materials, commercial products may be selected to meet implementation requirements. For example, the EPOSTAR series provided by Nippon Shokubai consists of crosslinked acrylate or melamine-formaldehyde resin microparticles, the surface of which may also carry functional groups such as amino or carboxyl groups depending on the model. For example, the Micropearl series (e.g., SP-203, SP-204) microparticles produced by Sekisui Chemical may also be used.

### <Abrasive Particles>

The abrasive particles 123 (which may also be referred to as second particles or hard particles) are distributed in the resin 121 and coexist in a mixture with the cleaning particles 122 and the hollow polymer microspheres 124. The main function of the abrasive particles 123 is to physically grind and cut the probe surface by utilizing their higher hardness, so as to remove contaminants (e.g., metal oxides, adhered solder). Therefore, the hardness of the abrasive particles 123 is set to be significantly higher than that of the cleaning particles 122. For example, the Mohs hardness of the abrasive particles 123 is greater than or equal to 7.

The material type of the abrasive particles 123 may be appropriately selected to provide sufficient cutting force. In an embodiment, the material of the abrasive particles 123 is selected from at least one of the group consisting of aluminum oxide (Al₂O₃), silicon carbide (SiC), diamond, quartz, and titanium dioxide (TiO₂). In an embodiment, the aluminum oxide may be selected from single-crystal aluminum oxide or polycrystalline aluminum oxide; the silicon carbide may be selected from green silicon carbide or black silicon carbide. These high hardness materials may effectively destroy the structure of contaminants, causing them to be stripped off from the probe surface.

The morphology of the abrasive particles 123 may be spherical or polygonal. In general, polygonal abrasive particles 123 or abrasive particles 123 with sharp angles have stronger cutting capability, while spherical abrasive particles 123 could provide a more uniform grinding effect. The particle size distribution of the abrasive particles 123 could be in a range from 0.02 micrometers to 50 micrometers. This particle size range has critical significance: if the particle size of the abrasive particles 123 is less than 0.02 micrometers, the grinding efficiency is extremely low, making it difficult to remove oxide layers of greater thickness; if the particle size of the abrasive particles 123 is greater than 50 micrometers, it is easy to cause excessively deep scratches on the probe surface, and may even damage the plating of the probe, shortening the probe's service life.

In an embodiment, the abrasive particles 123 may be selected from commercially available standard abrasive powders. For example, WA (white aluminum oxide) or GC (green silicon carbide) abrasive powders classified according to the JIS R 6001 standard may be selected, and the grit size thereof may correspond to the aforementioned particle size range (for example, #600 to #8000). In an embodiment, the abrasive particles 123 may be prepared by a sol-gel method or a powder sintering and pulverization method, and the particle size distribution thereof may be controlled by sieving or air classification technology to ensure uniformity of dispersion in the resin 121 and consistency of cleaning efficiency.

### <Hollow Polymer Microspheres>

In the cleaning layer 120, in addition to the aforementioned cleaning particles 122 and abrasive particles 123, hollow polymer microspheres 124 uniformly distributed in the resin 121 are further included. Each polymer microsphere has a substantially hollow structure. By means of the design of the hollow structure, the hollow polymer microspheres 124 may provide an appropriate or excellent buffering effect in the cleaning layer 120, reducing the friction force and impact force of the probe tip when contacting the decontamination material, thereby effectively reducing or even achieving zero probe wear, and significantly extending the service life of the probe card. Unlike solid filler particles, the hollow interior of the polymer microspheres provides a “micro-sink” for localized stress relief. Under the instantaneous impact of a probe tip, the thin-walled shell of the microspheres undergoes controlled buckling deformation, which significantly extends the effective cushioning stroke compared to a solid-particle-filled system. This dual-modulus behavior, where the cleaning layer maintains sufficient macroscopic integrity while exhibiting high microscopic compliance, enables the material to achieve near-zero wear on high-density probe arrays even under extreme overdrive conditions.

The material of the shell of the hollow polymer microspheres 124 may be appropriately selected. For example, the shell of the hollow polymer microspheres 124 commonly uses acrylonitrile-based polymers, acrylic-based polymers, or olefin-based polymers, and other suitable polymer materials or combinations of the aforementioned materials may also be used.

The morphology of the hollow polymer microspheres 124 may be spherical, or a geometric shape close to or similar to a sphere. In order for the decontamination material 100 to have an appropriate elastic stroke and initial anti-slip capability, the particle size distribution of the hollow polymer microspheres 124 may be appropriately selected. In an embodiment, the particle size distribution (for example, the average particle size) of the hollow polymer microspheres 124 could be in a range from 10 micrometers (μm) to 200 micrometers (μm). If the particle size is less than 10 micrometers, the compressible deformation amount that a single microsphere may provide is limited, and the elastic buffering stroke that the overall material may provide may be insufficient; if the particle size is greater than 200 micrometers, local raised structures may be formed on the surface of the cleaning layer 120, resulting in lateral slippage that may occur at the moment of probe contact due to insufficient interfacial anti-slip capability.

In an embodiment, an osmotic swelling method (also referred to as a seed swelling method) may be used to prepare the hollow polymer microspheres 124. In this method, a polymer containing hydrophilic or acidic groups (e.g., carboxyl groups) may be synthesized by emulsion polymerization and used as a core seed. Subsequently, a second-stage polymerization reaction is carried out on the exterior of the core seed to coat a polymer shell having a crosslinked structure. Thereafter, under appropriate temperature conditions, an alkaline substance or a volatile solvent (e.g., toluene) is added to cause the internal core seed to undergo neutralization or swelling, thereby expanding the outer polymer shell. Finally, through a drying procedure, the internal moisture or solvent is volatilized and removed, leaving a cavity inside the microsphere, thereby producing hollow polymer microspheres 124 having a hollow structure.

In an embodiment, a template method may be used to prepare the hollow polymer microspheres 124. In this method, inorganic or organic microparticles (e.g., silicon dioxide microparticles or appropriate low-molecular-weight copolymers) may be prepared as a sacrificial template. Subsequently, a crosslinked polymer shell layer is polymerized on the surface of the sacrificial template. Finally, corresponding chemical reagents (e.g., acidic or alkaline solutions) are used to dissolve and elute the internal sacrificial template, thereby clearing the core portion, and hollow polymer microspheres 124 having a stable hollow structure may be obtained.

In an embodiment, the hollow polymer microspheres 124 may also be achieved by selecting commercially available products. For example, microsphere products such as Expancel® 461 (manufactured by Nouryon and other manufacturers) may be selected, the shell of which is mainly composed of acrylonitrile-based copolymers and the interior of which is encapsulated with gas.

In an embodiment of the application and dispersion process, since the density of the hollow polymer microspheres 124 is extremely low (e.g., less than or approximately equal to 0.1 g/cm³), in order to uniformly disperse them in the resin 121, the hollow polymer microspheres 124 may first be subjected to surface wetting or pre-dispersion treatment, and then gradually introduced into the resin 121. The mixing process may be carried out using appropriate equipment such as a planetary centrifugal mixer and defoamer, under controlled stirring speed and mixing conditions, to reduce or avoid applying excessive shear force to the hollow polymer microspheres 124. This gentle and uniform dispersion method may reduce the probability or possibility of the hollow polymer microspheres 124 fracturing, collapsing, or deteriorating in the cured cleaning layer 120, so as to preserve the hollow structure as completely as possible to exert an appropriate buffering efficiency.

### <Resin Material>

In an embodiment, the chemical structure and physical properties of the resin 121, which serves as the matrix or binder of the cleaning layer 120, may be appropriately selected to ensure that the cleaning layer 120 maintains structural stability even under harsh testing environments. For example, the resin 121 is an organic silicone resin. From a microstructural perspective, the resin 121 may be a polyorganosiloxane having a highly cross-linked network structure.

The backbone structure of the resin 121 may be composed of silicon-oxygen bonds (Si—O bonds) formed by alternating connections of silicon atoms and oxygen atoms. The bond energy of the Si—O bond is extremely high (approximately 444 KJ/mol), far higher than that of the carbon-carbon bond (C—C bond, approximately 356 kJ/mol) of general organic polymers, and may avoid the problem of “carbonization contamination” under high-temperature testing environments. Therefore, the resin 121 may possess structural stability similar to that of inorganic materials (e.g., quartz and glass). This chemical structure imparts appropriate heat resistance performance to the resin 121, rendering it less prone to thermal cracking, thermal oxidation, or free radical chain scission reactions in high-temperature environments. In an embodiment, the resin 121 may operate stably over a wide temperature range of −50° C. to 250° C. for an extended period, and may withstand up to 300° C. or above of instantaneous high temperature in a short time. For example, if conventional carbon-based materials (e.g., epoxy resin or acrylic resin) are used, when the probe undergoes high-temperature testing (e.g., above 150° C.) or when frictional heat is generated due to continuous high-speed contact, these conventional resins are prone to thermal cracking, generating carbon residues, which instead adhere to the probe and become a contamination source that is difficult to remove. In an embodiment, this ensures that when the decontamination material 100 is applied to high-temperature wafer probing, the cleaning layer 120 is less likely or unlikely to undergo softening flow or embrittlement spalling.

The molecular weight characteristics of the resin 121 may have an influence on the mechanical strength and processing rheology of the material. In an embodiment, the weight-average molecular weight (Mw) of the resin 121 could be in a range from 30,000 to 800,000. If the molecular weight is lower than 30,000, the cured network structure may be too loose, resulting in insufficient cohesion; if the molecular weight is higher than 800,000, the viscosity of the resin may be too high, which may be unfavorable for the subsequent mixing and dispersion with particles.

In an embodiment, the glass transition temperature (Tg) of the resin 121 could be in a range from −60° C. to −20° C. This low Tg characteristic endows the resin 121 with good flexibility and rubber elasticity even in low-temperature environments, reducing or avoiding brittle fracture during low-temperature testing (cold test).

In order to endow the resin 121 with appropriate flexibility, processability, mechanical properties, and weather resistance, the resin 121 is modified by introducing corresponding organic functional groups onto the side chains of the silicon atoms. The organic functional groups may include methyl (−CH₃), vinyl (—CH═CH₂), or phenyl (−C₆H₅).

In an embodiment, regarding the appropriate synthesis method of the resin 121 and the means of introducing functional groups, appropriate silane monomers may be selected according to the target properties to undergo hydrolysis and condensation reactions. The resin 121 may be polymerized from various mixtures of monomers such as methyltrichlorosilane, dimethyldichlorosilane, phenyltrichlorosilane, diphenyldichlorosilane, or methylphenyldichlorosilane.

For example, if it is desired to introduce methyl (−CH₃) into the resin structure, methyltrichlorosilane or dimethyldichlorosilane may be selected as the reaction monomer. The introduction of methyl may endow the resin 121 with excellent water repellency and surface release properties. Since methyltrichlorosilane has three hydrolyzable chloro groups, it may serve as a cross-linking point in the condensation reaction, contributing to the formation of a dense three-dimensional network structure (T unit); whereas dimethyldichlorosilane may be applied to extend the length of the molecular chain, providing flexibility to the material.

For example, if it is desired to introduce phenyl (−C₆H₅) into the resin structure, phenyltrichlorosilane, diphenyldichlorosilane, or methylphenyldichlorosilane may be selected. The larger volume of phenyl (which may be referred to as steric hindrance) may disrupt the regularity of the polymer chain upon introduction, thereby suppressing crystallization, which helps maintain the flexibility of the material at extremely low temperatures. In addition, the high resonance stability of phenyl may further enhance the heat resistance and oxidation resistance of the resin 121. In general, the higher the phenyl content, the better the ablation resistance of the resin.

For example, if it is desired to introduce vinyl (—CH═CH₂) into the resin structure, monomers containing vinyl groups may be added during the polymerization process, such as vinyltrichlorosilane or methylvinyldichlorosilane, or dimethylvinylchlorosilane may be used for end-capping at the polymerization terminus. Vinyl is an appropriate reactive group for addition cure reactions. During the subsequent curing process, the vinyl groups on the side chains or at the termini may undergo hydrosilylation with a cross-linking agent (e.g., hydrogen-containing silicone oil) under the action of a platinum catalyst, thereby converting the resin 121 from a liquid state to a solid elastomer.

In an embodiment, in order to meet mass production requirements and implementation convenience, the resin 121 may optionally be a commercially available two-component addition-cure silicone rubber composition. For example, the Sylgard series produced by Dow Chemical Company (e.g., Sylgard 184), the KE series produced by Shin-Etsu Chemical Co., Ltd. (e.g., KE-106, KE-1031), or the RTV series products produced by Momentive Performance Materials Inc. may be selected. If a commercially available product is selected, the ratio may be further adjusted according to requirements, and/or the aforementioned monomers or modifiers may be additionally added to fine-tune the content of functional groups, thereby obtaining the resin 121 that meets the characteristic ranges described in the present disclosure. For example, “grafting via reactive end-groups” or “co-hydrolysis and condensation” may be employed for modification and preparation.

Taking the grafting via reactive end-groups method for modification using a commercially available base resin as an example, functionalization modification may be performed on a commercially available silicone resin of appropriate molecular weight (e.g., a polysiloxane fluid with silanol (—SiOH) or silyl hydride (—SiH) groups at the termini).

For example, if it is desired to introduce vinyl or phenyl groups onto a commercially available silanol-terminated polydimethylsiloxane (PDMS), a condensation reaction may be utilized. One possible approach is to dissolve the commercially available silanol-terminated polydimethylsiloxane in an organic solvent (e.g., toluene or xylene), and add a chlorosilane or alkoxysilane bearing the target functional group as a modifier. For another example, if it is desired to introduce vinyl, dimethylvinylchlorosilane or vinyltrimethoxysilane may be added. For another example, if it is desired to introduce phenyl, methylphenyldichlorosilane or diphenyldimethoxysilane may be added.

In the presence of a catalyst (e.g., dibutyltin dilaurate (DBTDL)) or an acid acceptor (e.g., pyridine), the reaction is carried out at 60° C. to 100° C. for 2 to 6 hours. The chloro groups or alkoxy groups on the modifier react with the silanol groups at the termini of the resin, eliminating hydrogen chloride or alcohol molecules, thereby bonding the vinyl or phenyl groups to the termini or side chains of the resin chain via chemical bonds (—Si—O—Si—).

Taking the co-hydrolysis and condensation method using commercially available base resins as an example, commercially available monomers bearing different functional groups may be directly used for copolymerization to appropriately adjust and control the ratio or distribution of methyl, phenyl, or vinyl groups in the resin molecular chain.

For example, if it is desired to introduce vinyl, commercially available vinyl monomers such as methylvinyldichlorosilane, vinyltrichlorosilane, or tetramethyltetravinylcyclotetrasiloxane may be used. Then, the aforementioned vinyl monomers are mixed with dimethyldichlorosilane (as a chain-extension monomer) and methyltrichlorosilane (as a network cross-linking monomer) at a predetermined molar ratio, and the mixture is added dropwise into a reaction tank containing water, an organic solvent (e.g., toluene), and isopropanol. The temperature is controlled below 50° C. to carry out a hydrolysis reaction to obtain silanol, followed by heating to reflux temperature (e.g., 100° C. to 110° C.) to carry out a dehydration condensation reaction (bodying step). By adjusting the amount of vinyl monomer added (e.g., 0.5% to 5% of the total molar number of monomers), the vinyl content in the resin 121 may be controlled, thereby determining the cross-linking density and hardness after curing.

For example, if it is desired to introduce phenyl, commercially available phenyl monomers such as phenyltrichlorosilane (PhSiCl₃), diphenyldichlorosilane (Ph₂SiCl₂), or methylphenyldichlorosilane (MePhSiCl₂) may be used. Then, the phenyl monomers and methyl monomers are subjected to co-hydrolysis. Since the hydrolysis rate of phenyl monomers is slower than that of methyl monomers, in order to reduce compositional non-uniformity (e.g., generation of homopolymers), a “dropwise addition method” or a co-solvent (e.g., acetone) may optionally be required to regulate the hydrolysis rate.

For example, if it is desired to introduce methyl, commercially available methyl monomers such as dimethyldichlorosilane, hexamethyldisiloxane, or trimethylchlorosilane may be used. The methyl monomers may serve as “end-capping” modification to allow the resin 121 to have an appropriate molecular weight range. For example, the addition of methyl monomers may cause the chain segments to stop growing. Thereby, the molecular weight of the resin may be adjusted within a preset range, or to have an appropriate ratio of functional groups.

### <Additives of the Cleaning Layer>

In an embodiment, in order to optimize the processability of the cleaning layer 120, the surface flatness after film formation, or to adjust the chemical reaction rate, in addition to the aforementioned resin 121, cleaning particles 122, abrasive particles 123, and hollow polymer microspheres 124, various functional additives may also be added to the composition of the cleaning layer 120. The additives may be selectively added or added in accordance with the corresponding reaction mechanism. The type and amount of the additives may be appropriately selected according to the actual formulation design.

In an embodiment, in order to promote the resin 121 to form the aforementioned highly cross-linked network structure, the raw material composition of the cleaning layer 120 may include a cross-linking agent (also referred to as a bridging agent). The type of the cross-linking agent is appropriately selected according to the reaction mechanism of the resin 121. When the resin 121 employs a polyorganosiloxane containing vinyl groups (e.g., an addition-type silicone resin system), the cross-linking agent may employ an organohydrogenpolysiloxane containing silyl hydride groups (Si—H). In this system, the cross-linking agent utilizes its silyl hydride groups to undergo a hydrosilylation reaction with the vinyl groups of the resin 121, thereby forming a three-dimensional network structure. In order to ensure sufficient curing without excessive residual reactive groups, the amount of the cross-linking agent added may be appropriately selected, for example, such that the molar ratio of silyl hydride groups to vinyl groups (H/Vi ratio) is in a range from 0.8 to 3.0. Commonly available commercial cross-linking agents include, for example, the X-92 series from Shin-Etsu Chemical or the Syl-Off series cross-linking agents from Dow.

In an embodiment, if the resin 121 employs polydimethylsiloxane containing no unsaturated bonds (e.g., a peroxide-type silicone resin system), the cross-linking agent may employ an organic peroxide, such as benzoyl peroxide (BPO) or 2,4-dichlorobenzoyl peroxide. In an embodiment, if the high cleanliness requirements of semiconductor testing are taken into consideration in the application, in order to reduce or avoid the release of reaction by-products, the aforementioned addition-type system (hydrosilylation) may be more suitable.

In an embodiment, in order to initiate or accelerate the aforementioned cross-linking reaction, a catalyst may be added to the cleaning layer 120. For the addition-type silicone resin system, the catalyst is typically selected from platinum-group metal catalysts (platinum-based catalysts), such as chloroplatinic acid, Karstedt's catalyst, or platinum-vinylsiloxane complexes. The content of the catalyst is typically very low, for example, approximately 1 ppm to 100 ppm by weight of metallic platinum relative to the total weight of the resin.

In an embodiment, in order to improve the surface flatness of the cleaning layer 120, and thereby optimize the total thickness variation (TTV) of the decontamination material 100, a leveling agent may be added to the cleaning layer 120. The type of the leveling agent may include modified polysiloxane, fluorine-based surfactants, or acrylic copolymers. In an embodiment, based on the total weight of the resin 121, the content of the leveling agent could be in a range from 0.05 wt % to 3 wt %. If the content of the leveling agent is too low, it may not be effective in eliminating orange peel or cratering phenomena during coating; if the content is too high, it may affect interlayer adhesion or contaminate the probes.

In an embodiment, in order to ensure uniform dispersion of the cleaning particles 122, abrasive particles 123, and hollow polymer microspheres 124 in the resin 121, and to avoid particle agglomeration, a dispersant may be added to the cleaning layer 120. Meanwhile, in order to eliminate air bubbles generated during the stirring or coating process, a defoamer may also be added. In the coating process, in order to adjust the viscosity to an appropriate coating range, a solvent, such as toluene, xylene, heptane, or methyl ethyl ketone (MEK), may also be added, and the solvent will be volatilized and removed during the subsequent drying process.

### <Formation Method of the Cleaning Layer>

In an embodiment, the preparation method of the cleaning layer 120 may be as follows. First, a coating liquid or colloidal composition for forming the cleaning layer 120 is prepared. For example, the aforementioned resin 121, cleaning particles 122, abrasive particles 123, and hollow polymer microspheres 124, or optionally other additives (e.g., cross-linking agents, catalysts, leveling agents, solvents, etc.) may be mixed according to a predetermined ratio. In an embodiment, the total weight percentage of the abrasive particles 123, cleaning particles 122, and hollow polymer microspheres 124 added to the resin 121 may be appropriately selected, for example, in a range from 10% to 400%. The setting of this addition ratio range may ensure that the cleaning layer 120 after film formation simultaneously possesses sufficient physical abrasive cutting force, contaminant adsorption force, and appropriate elastic buffer space.

In an embodiment, the control of the mixing process may be appropriately selected. For example, in order to enable the hollow polymer microspheres 124, which have an extremely low density, to be uniformly dispersed in the high-viscosity resin 121 (e.g., organosilicone resin), an appropriate viscosity adjustment or flowability improvement treatment may first be performed on the resin 121 (for example: adding an appropriate amount of solvent to adjust the viscosity). In addition, the hollow polymer microspheres 124 may first undergo surface wetting or pre-dispersion treatment before being introduced, in order to reduce the occurrence of agglomeration or floating. Subsequently, under controlled mixing conditions, the hollow polymer microspheres 124 are gradually introduced into the resin 121 for mixing. By the aforementioned method, the hollow polymer microspheres 124 may be promoted to form a uniformly distributed composite structure in the resin 121 matrix. In an embodiment, the mixing may be performed in a stirring device suitable for providing uniform mixing while avoiding excessive shear applied to the hollow polymer microspheres 124 (for example: a planetary centrifugal mixer/defoamer), and is not limited to a specific equipment type or operating conditions.

Next, the coating liquid that has been uniformly mixed and subjected to defoaming treatment is coated onto the surface of the support layer 110. The coating method may be appropriately selected, for example, techniques such as slot-die coating, micro-gravure coating, doctor blade coating, or comma coating may be employed to appropriately control the final thickness and surface flatness of the cleaning layer 120.

After the coating is completed, a curing procedure is performed on the coating liquid to form a solid cleaning layer 120. In order to ensure the structural integrity of the hollow polymer microspheres 124, the temperature profile of the curing process may be appropriately selected. In an embodiment, the curing procedure may include a pre-heating stage and a curing stage. The temperature of the pre-heating stage could be approximately in a range from 40° C. to 120° C., and the processing time could be in a range from a few minutes to tens of minutes. The temperature of the subsequent curing stage could be approximately in a range from 100° C. to 220° C., and the processing time could be in a range from a few minutes to tens of minutes. The heat treatment conditions of each of the aforementioned stages are based on the principle of not causing collapse, cracking, or deterioration of the hollow structure of the hollow polymer microspheres 124, and may be appropriately adjusted according to the shell material properties, particle size distribution, and substrate formulation of the hollow polymer microspheres 124.

By means of the aforementioned controlled composition ratios, low-shear dispersion process, and stepwise thermal curing reaction conditions, the cured cleaning layer 120 may obtain appropriate and expected overall physical properties (e.g., overall hardness performance and elastic modulus, etc.) under the premise of substantially minimizing damage to the microscopic hollow structure, thereby achieving excellent results in subsequent probe cleaning applications.

### <Physical Properties and Regulation of the Cleaning Layer>

In order to ensure that the cleaning layer 120 could effectively clean the probes while simultaneously taking into account the protection of the probes and avoiding the disintegration of the material itself, the macroscopic physical properties of the cleaning layer 120 (e.g., hardness, elastic modulus, and temperature resistance) may be appropriately selected and regulated. These appropriate physical properties will contribute to the cleaning layer 120 achieving excellent and stable decontamination effects during the subsequent actual cleaning process of repeated probe penetration and contact.

Regarding the hardness of the cleaning layer 120, the hardness of the cleaning layer 120 is defined by Shore A hardness. In an embodiment, the Shore A hardness value of the cleaning layer 120 could be in a range from 30 to 80. The setting of this hardness range has its physical considerations: if the Shore A hardness of the cleaning layer 120 is less than 30 (for example, in a range from 0 to 30), it generally means that the cross-linking degree of the resin 121 is relatively low and the material is excessively soft. In this state, the recovery of the cleaning layer 120 after being compressed by the probes is too poor, which will lead to a reduction in the overall cleaning capability. Conversely, if the Shore A hardness of the cleaning layer 120 is greater than 80 (for example, in a range from 80 to 100), it means that the cross-linking degree of the resin 121 is relatively high and the material properties are excessively rigid. When probe cleaning is performed in this excessively hard state, the cleaning layer 120 is prone to generating debris due to stress concentration, which not only reduces the cleaning capability but may also cause secondary contamination of the probes or test equipment.

In an embodiment, in order to comply with patent practices of various countries (e.g., the clarity requirements for enablement in Japanese patent practice), the hardness value of the cleaning layer 120 may be measured in accordance with international standards or Japanese Industrial Standards (JIS). For example, the cured cleaning layer 120 may be objectively tested and the numerical value may be obtained by using a Type A Durometer in accordance with standard test methods such as ASTM D2240 or JIS K 6253.

The hardness of the cleaning layer 120 may be regulated through various factors such as molecular structure and cross-linking density. Taking molecular structure as an example, the molecular structure of the resin 121 may be appropriately selected; if the molecular structure of the resin 121 contains more long carbon chains, the resin exhibits a softer performance; if aromatic hydrocarbons or structures with greater steric hindrance are introduced into the molecular structure, the rigidity of the molecular chains increases and the resin exhibits a more rigid performance. Taking cross-linking density as an example, cross-linking density is proportional to the cohesion of the material. Low cross-linking density results in low cohesion; high cross-linking density results in high cohesion. The weight percentage of the bridging agent added to the resin 121 could be in a range from 10% to 60%. If the content of the bridging agent is less than 10%, the cross-linking density is too low, the hardness is relatively soft, the recovery is too poor, and the cleaning capability is reduced; if the content of the bridging agent is greater than 60%, the cross-linking density is too high, the hardness is relatively hard, and debris is prone to be generated during probe cleaning.

Regarding the elastic modulus (also known as Young's modulus) of the cleaning layer 120, the magnitude of the elastic modulus indicates the degree of rigidity of the material. The greater the elastic modulus, the less likely deformation is to occur; the lower the elastic modulus, the more likely deformation is to occur. In an embodiment, the elastic modulus of the cleaning layer 120 could be in a range from 15 kg/cm² to 350 kg/cm²; for example, in a range from 40 kg/cm² to 200 kg/cm². This numerical range contributes to effectively cleaning the probes. If the elastic modulus is less than 15 kg/cm², the recovery of the material after compression is too poor, which will reduce the cleaning capability. If the elastic modulus is greater than 350 kg/cm², the material is excessively rigid, and debris is prone to be generated during probe cleaning, which not only reduces the cleaning capability but may even cause secondary contamination.

In an embodiment, the elastic modulus value of the cleaning layer 120 may be measured in accordance with standard tensile test methods, for example, in accordance with ASTM D412 or JIS K 6251 standards, by preparing test specimens of an appropriate shape (e.g., dumbbell-shaped) and performing tensile testing, and the elastic modulus value may be calculated and obtained from the linear region of the stress-strain curve.

The elastic modulus of the cleaning layer 120 may be regulated through factors such as molecular weight, glass transition temperature (Tg), or the ratio of cleaning material to the resin 121. Taking molecular weight as an example, the molecular weight of the resin 121 may be selected in a range from 30,000 to 800,000. A lower molecular weight is unfavorable for cohesion, resulting in a lower elastic modulus; a higher molecular weight is favorable for cohesion, resulting in a higher elastic modulus. Taking glass transition temperature as an example, the Tg of the resin 121 may be selected in a range from −60° C. to −20° C. A low Tg corresponds to poorer cohesion, a lower elastic modulus, and poorer temperature resistance; a high Tg corresponds to better cohesion, a higher elastic modulus, and better temperature resistance. In addition, the weight percentage of cleaning material (including the aforementioned solid components such as cleaning particles 122, abrasive particles 123, and hollow polymer microspheres 124) added to the resin 121 could be in a range from 10% to 400%. The elastic modulus may be effectively adjusted by adding different types of cleaning material to the resin 121 or by adjusting the proportions of different cleaning materials.

Regarding temperature resistance, the cleaning layer 120 has excellent high heat resistance, and its operating and temperature resistance range could be in a range from −50° C. to 300° C. This excellent heat resistance performance mainly originates from the resin 121 (for example, silicone material) having a backbone structure with high bond energy. The backbone is connected by Si—O bonds composed of silicon and oxygen, which have structural stability similar to inorganic materials (e.g., quartz and glass), and are not prone to reactions such as thermal cracking, thermal oxidation, or free radical scission in high-temperature environments. At the same time, by introducing organic functional groups such as methyl (—CH₃), vinyl (—CH—CH₂), or phenyl (—C₆H₅) into the side chains of the silicon atoms, appropriate flexibility and processability are imparted to the material, further enhancing its mechanical properties and weather resistance. In addition, the resin 121 has a low glass transition temperature and a high decomposition temperature; therefore, the cleaning layer 120 may operate stably over a long period within the range of −50° C. to 250° C., and may withstand up to 300° C. or above instantaneous high-temperature test environments in a short time.

In an embodiment, the weight percentage of hollow polymer microspheres 124 (or cleaning material, including cleaning particles 122, abrasive particles 123, and hollow polymer microspheres 124) added to the resin 121 could be in a range from 5 wt % to 350 wt %. Within this numerical range, the decontamination material may provide stable cleaning efficiency with a high yield rate and no risk of secondary contamination under long-term operation (e.g., at least 1,500 times).

### <Usage of Decontamination Material>

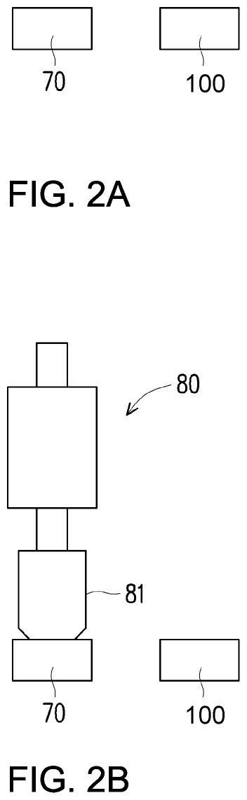

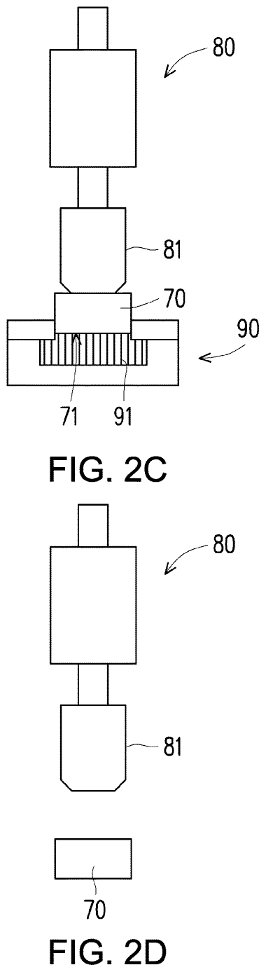

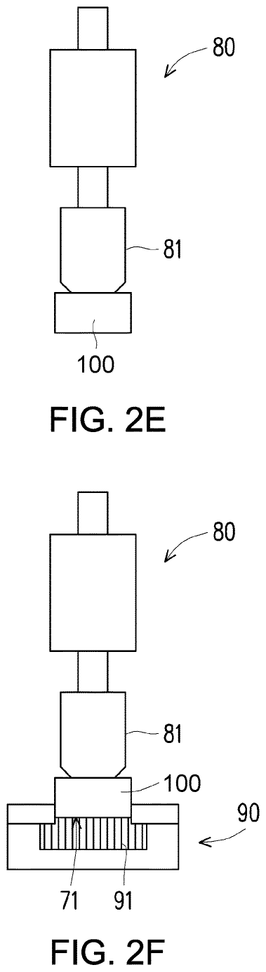

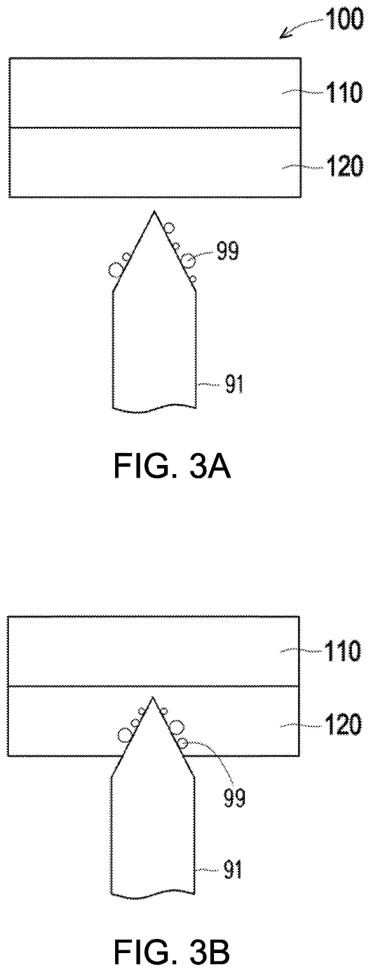

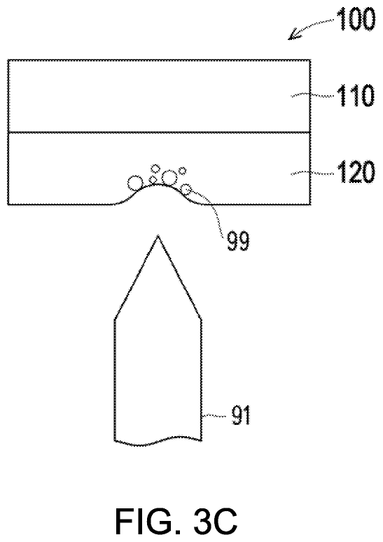

FIG. 2A to FIG. 2F are schematic diagrams of a usage of a decontamination material (or: a cleaning method of probes) according to one embodiment of the present disclosure. In addition, for the sake of clarity or conciseness, the decontamination material 100 in FIG. 2A to FIG. 3C is illustrated only schematically, and the support layer 110, the cleaning layer 120, the cleaning particles 122, the abrasive particles 123, and the hollow polymer microspheres 124 in the cleaning layer 120 may be omitted from the illustration.

Please refer to FIG. 2A to FIG. 2C, an electrical test may be performed on the electronic component 70 by the probe 91 using a generally common testing method.

Taking FIG. 2A as an example, the electronic component 70 and the decontamination material 100 (including the support layer 110 and the cleaning layer 120) are provided.

In an embodiment, the electronic component 70 is, for example, a bare die or a chip package, but the present disclosure is not limited thereto.

Then, as shown in FIG. 2B, the electronic component 70 to be tested may be picked up by the pick-and-place head 81 of the pick-and-place device 80.

Then, as shown in FIG. 2C, the electronic component 70 to be tested may be placed on the test device 90 by the pick-and-place device 80.

The test device 90 includes, for example, a plurality of probes (probe pins) 91. The probes 91 may contact conductive terminals (e.g., solder balls) (not shown) or contact pads (not shown) on the tested surface 71 of the electronic component 70, so as to test the electronic component 70. For example, pressure may be applied to the electronic component 70 to be tested and/or the probes 91, so that the conductive terminals or contact pads on the tested surface 71 of the electronic component 70 to be tested come into contact with the probes 91.

In an embodiment, the testing method is, for example, a final test (FT), but the present disclosure is not limited thereto. In an embodiment, the testing method may be a chip probing (CP).

After the exemplary testing in the aforementioned FIG. 2A to FIG. 2C, the probes 91 may be cleaned by the decontamination material 100 in a similar manner of operation.

Taking FIG. 2C to FIG. 2D as an example, after testing the electronic component 70, the electronic component 70 may be separated from the probes 91, and the electronic component 70 may be placed by the pick-and-place device 80.

In an embodiment, during the process of the electronic component 70 coming into contact with and/or separating from the probes 91, part of the substance on the electronic component 70 (e.g., solder forming the conductive terminals or aluminum, zinc, or copper forming the contact pads) may be peeled off and adhered to the probes 91.

Then, as shown in FIG. 2E, the decontamination material 100 may be picked up by the pick-and-place head 81 of the pick-and-place device 80.

Then, as shown in FIG. 2F, the decontamination material 100 may be placed on the test device 90 by the pick-and-place device 80, so as to clean the probes 91 by the decontamination material 100.

For example, pressure may be applied to the decontamination material 100 and/or the probes 91, so as to bring the decontamination material 100 into contact with the probes 91, so that the substance 99 (e.g., solder, aluminum, zinc, copper, or possible contaminants; labeled or illustrated in FIG. 3A to FIG. 3C) adhered to the probes 91 is adhered by the cleaning layer 120 of the decontamination material 100. Thereafter, the decontamination material 100 may be separated from the probes 91, and the substance 99 adhered to the probes 91 may be reduced by the decontamination material 100.

In more detail, reference is made to FIG. 3A to FIG. 3C.

As shown in FIG. 3A to FIG. 3B, one end of the probe 91 used for testing (e.g., the end used for contacting the electronic component 70) may penetrate into the cleaning layer 120 of the decontamination material 100. The substance 99 adhered to the probe 91 may be loosened from the probe 91 by the abrasive particles 123 in the cleaning layer 120. For example, during the process of the probe 91 penetrating into the cleaning layer 120, the substance 99 on the probe 91 may rub against the abrasive particles 123 in the cleaning layer 120. Moreover, since the substance 99 originally adhered to the probe 91 may have already been loosened from the probe 91, the cleaning particles 122 in the cleaning layer 120 may more easily remove the substance 99 from the probe 91.

In addition, during the process of the probe 91 penetrating into and contacting the cleaning layer 120, the hollow polymer microspheres 124 uniformly distributed within the cleaning layer 120 exert an appropriate or excellent buffering effect. By virtue of their unique hollow structure, the hollow polymer microspheres 124 are capable of generating appropriate elastic deformation to absorb the impact force when the probe 91 is pressed down, and effectively reducing the friction force at the probe tip 91 upon contact. This enables the decontamination material 100 to significantly reduce the substantial wear caused to the probes 91 while retaining the powerful decontamination capability of the high hardness abrasive particles 123, and may even achieve an excellent protective state of nearly zero wear, thereby greatly extending the service life of the probes 91 and the probe card.

As shown in FIG. 3C, during the process of the probe 91 separating from the cleaning layer 120, a large portion of the substance 99 removed from the probe 91 may be embedded, encapsulated, or trapped within the resin 121. In this way, during the separation process described above, the possibility of the substance 99 re-adhering and re-attaching to the probe 91 may be reduced.

In an embodiment, within a unit volume, since the total number of the cleaning particles 122 and the hollow polymer microspheres 124 in the cleaning layer 120 is greater than the number of the abrasive particles 123, in this way, a large portion of the substance 99 removed from the probe 91 may more easily be embedded, encapsulated, or trapped within the resin 121 by the cleaning particles 122, and/or the possibility of the removed substance 99 detaching from the decontamination material 100 due to the withdrawal of the probe 91 during the separation process of the decontamination material 100 from which the probe 91 has penetrated may be reduced. Therefore, the decontamination material 100 may have a greater number of effective uses. Moreover, after the decontamination material 100 is separated from the probes 91, the amount of the substance 99 adhered to and/or encapsulated on the probes 91 may be significantly reduced.

In an embodiment, even during the process of the probe 91 contacting and/or separating from the cleaning layer 120, the high hardness abrasive particles 123 may (but the possibility of “not” is not excluded) generate corresponding scratches on the probe 91. However, since the particle size of the abrasive particles 123 may be appropriately selected (e.g., approximately 0.02 micrometers to 50 micrometers), together with the elastic deformation and impact absorption capability provided by the hollow polymer microspheres 124, the size and/or traces of the scratches (if any) may be greatly reduced, further reducing the possibility of a decrease in the performance of the probe 91 in subsequent use due to the scratches (if any).

In the method or steps of cleaning the probes 91 by the decontamination material 100 of any of the aforementioned embodiments of the present disclosure, the probes 91 may not be disassembled or separated from the test device 90. Moreover, the cleaning of the probes 91 may be performed by the same or similar operating parameters (recipe) as those used for testing the electronic component 70. That is, the steps of the cleaning method of the probes 91 may be performed in-situ or on-line.

It should be noted that FIG. 2A to FIG. 3C are provided for illustrative purposes only to describe a cleaning method for the probes 91, and the present disclosure is not limited to any specific type of the probes 91. For example, in FIG. 2A to FIG. 3C, the probes 91 illustrated are vertical probe pins, but the present disclosure is not limited thereto. In an embodiment not illustrated, the decontamination material 100 of any of the aforementioned embodiments of the present disclosure may also be used for cleaning cantilever probe pins in a manner similar to a general testing method. Furthermore, it should be appreciated by those skilled in the art that the decontamination material disclosed herein is substantially or fundamentally distinct from, and is not intended to serve as, a polishing pad utilized in semiconductor chemical mechanical planarization (CMP) processes.

### [EXPERIMENTS] AND [EXAMPLES]

The experiments and examples presented below (including all experimental examples and comparative examples) are provided to specifically illustrate the present disclosure. The aforementioned embodiments of the present disclosure may include the following experimental examples or partial experimental results, but the embodiments of the present disclosure are not limited by the following experiments or experimental examples.

Among the various examples, the main differences lie in the relative conditional relationships (e.g., variables) described in each experiment. Accordingly, apart from the variable, the remaining conditions constituting the decontamination material, the type, proportion, and particle size distribution of the abrasive particles, cleaning particles, and/or hollow polymer microspheres, the material and thickness of the support layer, and the total thickness of the support layer and the cleaning layer, are all maintained substantially the same or similar, thereby facilitating an effective observation of the differences in effects attributed to the variable. The specific formulations and test results described below are used to illustrate the technical principles and effects of the present disclosure, and are not intended to impose any limitation on the scope of the present disclosure.

### Experiment 1

The purpose of [Experiment 1] is to confirm that the manufacturing method of the decontamination material of the present disclosure (in particular, the formation method of the cleaning layer and the thermal curing conditions) does not cause the hollow polymer microspheres to collapse, rupture, or undergo degradation of the hollow structure, so as to ensure that they may provide excellent elastic buffering and shock absorption effects in actual probe cleaning applications.

In [Experimental example 1], the hollow polymer microspheres added to the cleaning layer are commercially available polymer microspheres, specifically for example Expancel® 461 hollow polymer microspheres produced by Nouryon, the shell of which is mainly composed of an acrylonitrile-based copolymer.

The specific formation method of the cleaning layer of [Experimental example 1] is included in the manufacturing method of the aforementioned embodiments, with appropriate and controlled parameter ranges. Since the hollow polymer microspheres have an extremely low density, in order to uniformly disperse them in a high-viscosity resin, the viscosity of the resin 121 is first appropriately adjusted, and after the hollow polymer microspheres are subjected to surface wetting treatment, they are gradually introduced into the resin 121 together with the cleaning particles and abrasive particles. The mixing process is carried out using a planetary centrifugal mixer under controlled low-shear conditions for uniform mixing and defoaming, so as to reduce the risk of damaging the hollow structure of the microspheres. Subsequently, the mixed coating liquid is coated onto the support layer and cured. Within the maximum allowable range of the process, the curing procedure includes a preheating stage (temperature approximately in a range from 40° C. to 120° C., processing time in a range from several minutes to several tens of minutes) and a curing stage (temperature approximately in a range from 100° C. to 220° C., processing time in a range from several minutes to several tens of minutes). In the specific operation of [Experimental example 1], the temperature profile of the curing procedure is specifically set as follows: preheating is first performed at an environment of approximately 80° C. for approximately 20 minutes, followed by raising the temperature to approximately 150° C. for thermal curing for approximately 1 hour.

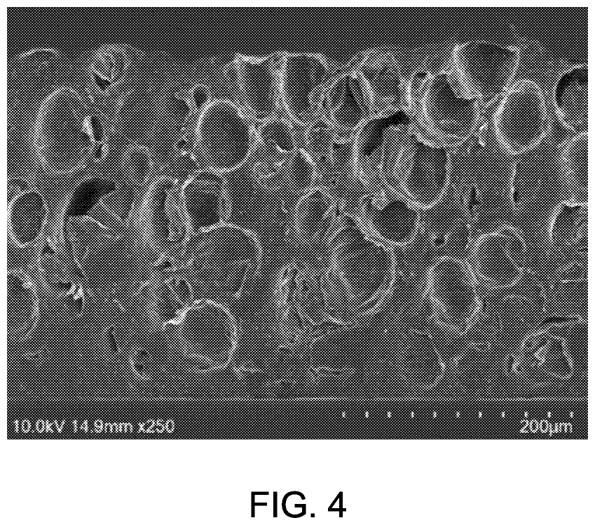

FIG. 4 is an enlarged view of a partial cross-section of the decontamination material of [Experimental example 1] according to the present disclosure in a completed and unused state, observed at 250× magnification by a scanning electron microscope (SEM).

Please refer to FIG. 4. From the SEM cross-sectional observation image, it could be clearly seen that a large number of hollow polymer microspheres are uniformly distributed in the resin matrix of the cleaning layer. After the aforementioned low-shear mixing process and the stepwise thermal curing conditions of “preheating at approximately 80° C. for approximately 20 minutes, followed by curing at approximately 150° C. for approximately 1 hour,” these hollow polymer microspheres still maintain an extremely intact spherical or quasi-spherical appearance at the microscopic level. The thin-walled acrylonitrile-based copolymer shell structure remains intact, and no obvious phenomena of collapse, rupture, or deformation caused by thermal stress or mechanical shear force are substantially observed, and the internal cavity (hollow structure) thereof is also almost appropriately preserved. This microscopic verification result of microsphere integrity strongly and directly demonstrates that the dispersion process and the specific temperature curing profile adopted by the present disclosure could effectively overcome the challenges of agglomeration and rupture of lightweight hollow microspheres during processing, thereby ensuring that the hollow polymer microspheres could truly exert the expected technical effects of elastic buffering and wear reduction in the cleaning layer.

### Experiment 2

The purpose of [Experiment 2] is to confirm the effect of the addition amount of the hollow polymer microspheres in the cleaning layer on the apparent microstructure of the decontamination material under repeated use, as well as the actual wear protection effect on the probe. The hollow polymer microspheres used in [Experiment 2] are the same as those in [Experiment 1], for example, commercially available hollow polymer microspheres having a shell composed of an acrylonitrile-based copolymer.

In the test method of [Experiment 2], in order to highly simulate the actual test scenario of a semiconductor assembly and test factory, crown head probes used in integrated circuit (IC) chip testing (e.g., a type of probe) are directly used for testing. The test conditions are set to simulate the process after testing an integrated circuit (IC) chip, wherein 10 touch-down cleaning cycles (Touch Down) are performed on the decontamination material sample, and this testing and cleaning procedure is continued until a total of 1500 cleanings are cumulatively completed on the sample. After the test is completed, the wear amount of the probe tip is measured by precision instruments, and the morphological changes of the surface of the decontamination material are observed by a scanning electron microscope (SEM). The results of [Experiment 2] are listed in [Table 1] below.

TABLE 1

| | Experimental | Experimental | Experimental | Experimental | Experimental |
|---|---|---|---|---|---|
| | example | example | example | example | example |
| | 2-1 | 2-2 | 2-3 | 2-4 | 2-5 |
| Hollow polymer | 0 | 4 | 5 | 350 | 400 |
| microsphere | | | | | |
| addition ratio | | | | | |
| (wt %) | | | | | |
| Probe tip wear | 3 | 1 | 0 | 0 | 0 |
| amount (μm) | | | | | |

In [Table 1], if the measurement result after the test is completed shows that the wear amount is less than the detection limit of the instrument, or falls within the detection error range, the wear amount is marked as 0 μm, indicating that the probe has almost no wear.

Based on a comprehensive technical analysis of the wear test data of the probe above, if the addition amount of the hollow polymer microspheres is too small (e.g., less than 5 wt %, corresponding to [Experimental example 2-1] and [Experimental example 2-2]), the buffering effect is insufficient due to the inability to establish a sufficiently dense buffer air chamber network inside the cleaning layer, and the probe will still produce a corresponding and significant wear amount when in contact with and rubbing against abrasive particles having high hardness. Conversely, when the addition amount reaches 5 wt % or more, the critical vibration damping and impact absorption functions could be exerted, achieving an excellent protection effect of zero wear.

In addition, in order to further investigate the effect of the addition amount of the hollow polymer microspheres on the macroscopic and microscopic structures of the decontamination material, the surface is locally observed by SEM below.

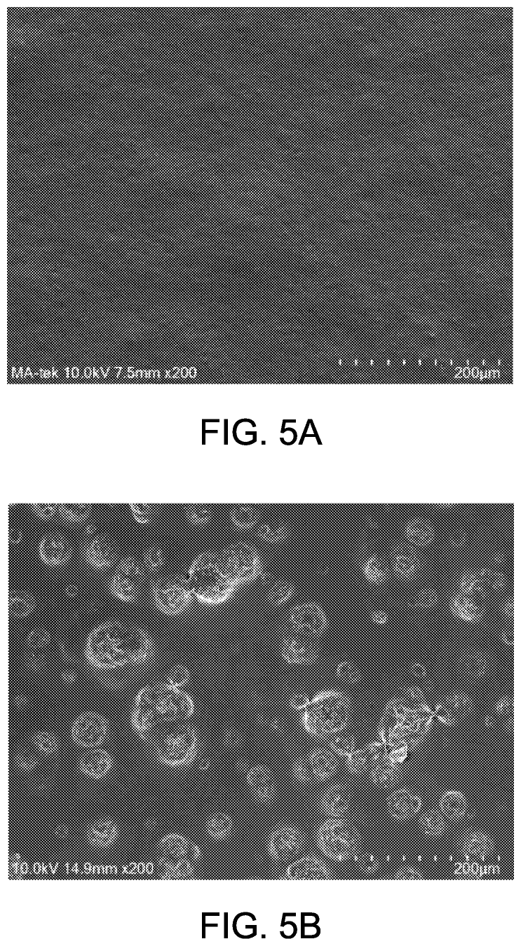

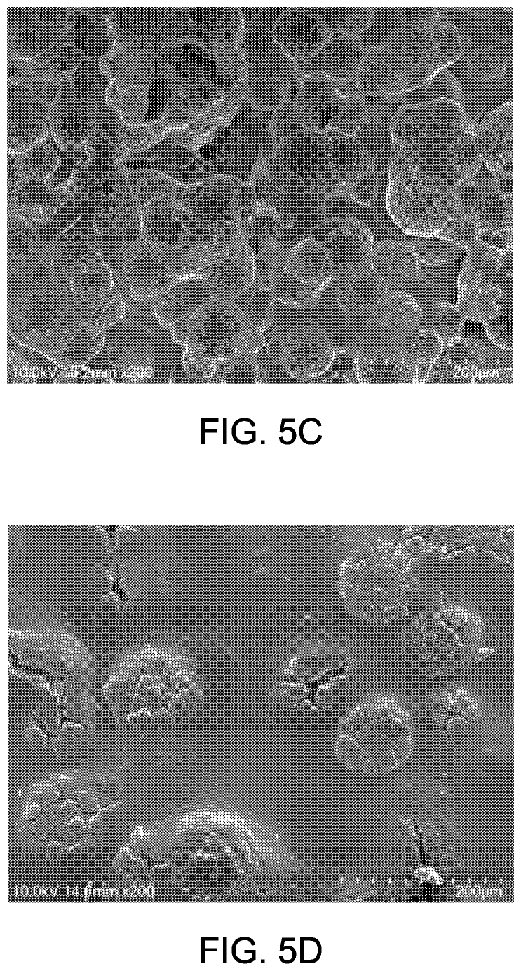

FIG. 5A is a SEM local surface magnified view at 200× magnification of the decontamination material according to [Experimental example 2-1] of the present disclosure in a state of having been fabricated and not yet used. As shown in FIG. 5A, since no hollow polymer microspheres are added (0 wt %), the resin matrix encapsulates the particles to form a relatively smooth, dense, and pore-free surface. Although this structure is solid, it lacks microscopic deformation space for absorbing the downward impact force of the probe.

FIG. 5B is a SEM local surface magnified view at 200× magnification of the decontamination material according to [Experimental example 2-3] of the present disclosure in a state of having been fabricated and not yet used. As shown in FIG. 5B, when 5 wt % of hollow polymer microspheres are added, small mound-like protrusions and spherical contours supported by the microspheres begin to appear on the surface of the cleaning layer. These uniformly distributed microsphere structures are intact and have not ruptured, providing a preliminary and effective elastic buffer region for the probe.

FIG. 5C is a SEM local surface magnified view at 200× magnification of the decontamination material according to [Experimental example 2-4] of the present disclosure in a state of having been fabricated and not yet used. As shown in FIG. 5C, when the addition amount is as high as 350 wt %, the surface exhibits highly dense spherical protrusions, and the hollow polymer microspheres form a continuous and abundant pore network in the resin. It is worth noting that under this extremely high concentration of addition, the shell of the microspheres still maintains an intact closed structure, and no rupture phenomenon is observed, indicating that the structural robustness of the material is still sufficient to support the repeated penetration of the probe.

FIG. 5D is a SEM local surface magnified view at 200× magnification of the decontamination material according to [Experimental example 2-5] of the present disclosure in a state of having been fabricated and not yet used. Referring to the SEM image of FIG. 5D, if the addition amount of the hollow polymer microspheres is too high (e.g., greater than 350 wt %, here being 400 wt %), severe rupture and surface cracking phenomena of the spherical structures on the surface of the cleaning layer could be clearly observed. If analyzed from the perspective of polymer materials science, this phenomenon may be due to the fact that the excessive amount of microspheres has exceeded the limit that the resin matrix could encapsulate and bond. This microscopic structural damage will cause structural disintegration of the decontamination material when subjected to the downward compressive stress of the probe (e.g., generation of corresponding particles, dust, and other debris), which will not only cause secondary contamination of the test equipment, but will also cause the cleaning layer to lose its capability of capturing contaminants, resulting in a significant decrease in cleaning performance.

### Experiment 3

The purpose of [Experiment 3] is to confirm the effect of the particle size of the hollow polymer microspheres in the cleaning layer on the buffering effect and contact stability of the overall decontamination material. In this experiment, the material type of the hollow polymer microspheres is the same as or similar to that of [Experiment 1], with the only difference being that the average particle size specifications of the selected microspheres are different.

In order to objectively and quantitatively evaluate the buffering effect, [Experiment 3] measures and confirms the compression ratio of the cleaning layer. The specific test method is as follows: cleaning layer samples containing hollow polymer microspheres of different particle sizes are each cut into 30 mm×30 mm square pieces, and multiple pieces of test specimens of the same specification are neatly stacked so that the total initial thickness reaches approximately 10 mm. During testing, the stacked samples are placed at the center of the test platform (e.g., a Lower Platen) of a precision test equipment, and a jig (e.g., a T-Block fixture) is lowered until it just contacts the surface of the sample, and the height at this point is recorded as the initial thickness before the start of the test. Subsequently, the equipment presses down at a steady speed and applies a fixed preset pressure (e.g., 5 kgf) to the sample, and the compressed thickness reduction caused by the displacement of the fixture under this fixed pressure is recorded. The final compressibility confirmation is obtained by dividing the initial thickness before the start of the test by the thickness reduction after compression, and converting it into a percentage as the “Compression Ratio.” By means of this non-destructive testing method, the differences in support performance and elastic deformation brought about by different microsphere particle sizes under the same formulation could be accurately compared.

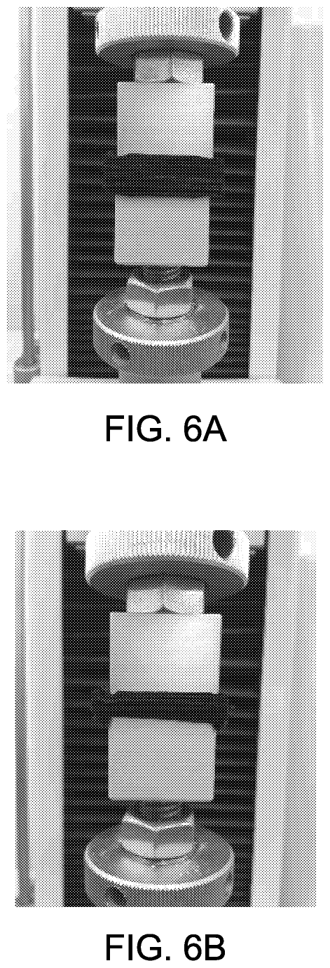

FIG. 6A to FIG. 6B are partial operation schematic photographs (or test photographs) of the compression ratio test performed on the cleaning layer in [Experiment 3]. Referring to FIG. 6A and FIG. 6B, it could be clearly observed that before and after the jig (e.g., the T-Block fixture) applies the preset pressure, the stacked samples produce corresponding elastic compressive deformation in the thickness direction.

In addition, since the probe makes contact with the surface of the cleaning layer of the decontamination material in an “instantaneous contact (Touch Down)” manner of extremely short time during actual testing, whether lateral displacement of the probe tip (e.g., the needle sliding phenomenon) occurs depends primarily on the initial anti-slip capability that could be provided by the interface at the moment of contact. Therefore, the experiment also uses a standard metal steel plate as an equivalent metal contact body of the probe, and objectively evaluates the risk of slippage of the probe at the moment of contact by measuring the static friction coefficient (Static Friction Coefficient) between it and the surface of the finished product of each example. Regarding the measurement of the static friction coefficient, standard test methods commonly used in the industry are adopted. For example, the measurement may be performed in accordance with international standards such as ASTM D1894 (Standard Test Method for Static and Kinetic Coefficients of Friction of Plastic Film and Sheeting) or JIS K 7125 (Equipment for measuring the static and dynamic coefficient of friction in plastic films).

The specific test results of [Experiment 3] are shown in [Table 2].

TABLE 2

| | Experimental | Experimental | Experimental | Experimental | Experimental |
|---|---|---|---|---|---|
| | example | example | example | example | example |
| | 3-1 | 3-2 | 3-3 | 3-4 | 3-5 |
| Hollow polymer | 8 | 10 | 80 | 200 | 210 |
| microsphere | | | | | |
| average particle | | | | | |
| size (μm) | | | | | |
| Compression | 23.9 | 36.1 | 42.4 | 47.2 | 57.4 |
| ratio (%) | | | | | |
| coefficient of | 0.994 | 1.135 | 1.293 | 1.187 | 0.958 |
| static friction | | | | | |

As shown by the data of [Experiment 3], when the average particle size of the hollow polymer microspheres is approximately 80 μm (as in [Experimental example 3-3]), the finished product simultaneously possesses a relatively high compression ratio (42.4%) and the highest static friction coefficient (1.293). This result indicates that, at this particle size specification, the gas chamber space inside the microspheres could provide the optimal elastic stroke to absorb the overdrive stress of the probe upon pressurized contact; at the same time, the microstructure formed on the resin surface could closely conform to the metal contact body, providing excellent initial anti-slip capability at the moment of contact, ensuring that the contact landing point of the probe tip is stable and no lateral displacement occurs.

As shown by the data of [Experiment 3], when the average particle size of the hollow polymer microspheres increases to 200 μm or above (as in [Experimental example 3-4] to [Experimental example 3-5]), although the overall compression ratio is further improved (reaching 47.2% to 57.4%) due to the larger microsphere volume, the static friction coefficient shows a reverse decline (dropping to 1.187 or even 0.958). From the perspective of microscopic geometric structure, an excessively large particle size tends to form overly prominent “local raised structures (e.g., macro-roughness)” on the surface of the cleaning layer, resulting in a reduction in the actual contact area of the probe tip (or equivalent metal steel plate). In actual semiconductor testing applications, this means that at the moment of contact, the probe is highly prone to “lateral sliding (e.g., skating effect)” along the edges of the large microspheres due to insufficient initial anti-slip capability at the interface, thereby causing instability of the contact landing point, abnormal fluctuation of contact resistance (Cres), and potentially even irreversible bending damage to the probe.

As shown by the data of [Experiment 3], when the average particle size of the hollow polymer microspheres is less than approximately 10 μm (as in [Experimental example 3-1]), although the static friction coefficient (0.994) is not significantly lower than that of the preferred particle size range, the compression ratio is only approximately 23.9%. From the perspective of polymer mechanics, this indicates that the free volume (Free volume) and the compressible deformation contained within a single minute microsphere are excessively limited. When the probe presses down at high speed, the overall elastic buffer stroke that the cleaning material could provide is insufficient, and the probe tip may still bear a relatively large rigid reaction force, thereby aggravating the degree of wear of the probe.

Based on the above comprehensive analysis, the present disclosure clearly defines the average particle size range of the hollow polymer microspheres through experimental data (for example: greater than or approximately equal to 10 μm, and less than 200 μm). Furthermore, by selecting the average particle size of the hollow polymer microspheres within this numerical range, the trade-off between “insufficient buffer stroke (e.g., particle size too small)” and “contact landing point sliding (e.g., particle size too large)” may be overcome, thereby enabling the decontamination material to maintain extremely high testing precision and stability while reducing probe wear, satisfying the requirements of advanced semiconductor testing processes.

### Experiment 4

The purpose of [Experiment 4] is to confirm the effect of the type of spheres added to the cleaning layer on probe cleaning.

### [Cleaning Effect Test]

To evaluate the cleaning efficiency of the decontamination material samples, the actual testing process of assembly and testing factories was simulated. The testing conditions were set such that after every 50 identical integrated circuit chips (IC) were tested, a cleaning cycle of 10 probe stabs was performed on the decontamination material samples, and this testing and cleaning process was continued until a total of 1500 cleanings were cumulatively completed on the samples. Crown-head probes were used throughout the entire test, and the effectiveness was evaluated using two key indicators of in-line electrical testing: yield rate (Yield Rate) and open/short rate (O/S Rate).

The yield rate is a core indicator in semiconductor manufacturing, one definition of which is: the percentage of the number of ICs determined to be functionally normal through electrical testing out of the total number of ICs. Probe testing is a critical step in determining this initial yield rate, and its accuracy is of paramount importance. If the probes are contaminated due to insufficient cleaning, it may cause instability in contact resistance, thereby leading to the misidentification of functionally normal ICs as defective products, resulting in yield loss. Therefore, whether the decontamination material could continuously help the cleaned probes maintain a high and stable yield rate over extended testing periods is an important standard for evaluating its cleaning efficiency.

The probe wear evaluation method as described in the aforementioned [Experiment 2] was also adopted in [Experiment 4]. Specifically, the wear amount of the probe is calculated by subtracting the probe length after the test from the initial probe length.

In addition, [Experiment 4] also adopted the compression method as described in the aforementioned [Experiment 3] to perform compression testing on the material, and evaluated the elastic rebound performance after compression. Specifically, the calculation of elastic rebound performance is defined as: the thickness after compression unloading and standing divided by the initial thickness before compression.

[Experimental example 4-1] adopts the same polymer hollow microspheres as the aforementioned [Experimental example 1]. Specifically, commercially available hollow polymer microspheres with an acrylonitrile-based copolymer shell are used (e.g., Expancel® 461). The actual density (true density) of the hollow microspheres is approximately in a range from 0.01 g/cm³ to 0.08 g/cm³, and the shell/shell wall thickness is approximately in a range from 0.1 μm to 1.0 μm.

[Experimental example 4-2] replaces the microspheres with commercially available hollow glass microspheres (e.g., 3M microsphere). The actual density (true density) of the hollow glass microspheres is approximately in a range from 0.1 g/cm³ to 0.8 g/cm³, and the shell/shell wall thickness is approximately in a range from 0.5 μm to 10 μm.

[Experimental example 4-3] replaces the microspheres with hollow polymer microspheres of polymethylmethacrylate (PMMA) having a specific degree of crosslinking. The actual density (true density) of the crosslinked PMMA hollow microspheres is approximately in a range from 0.02 g/cm³ to 0.1 g/cm³, and the shell/shell wall thickness is approximately in a range from 0.1 μm to 1.0 μm.

In order to conduct an objective comparative analysis, [Experiment 4] uses the test results of [Experimental example 4-1] as a benchmark to evaluate the performance of [Experimental example 4-2] and [Experimental example 4-3]. That is, the elastic rebound performance, probe wear amount, and probe cleaning efficiency measured in [Experimental example 4-1] are all set to 100% (normalized standard).

The specific test results of [Experiment 4] are shown in [Table 3].

TABLE 3

| | Experimental | Experimental | Experimental |
|---|---|---|---|
| | example | example | example |
| | 4-1 | 4-2 | 4-3 |
| microsphere material | acrylonitrile- | hollow glass | Cross-linked |
| | based polymer | microspheres | PMMA |
| | microspheres | | microspheres |
| Elastic rebound | 100 | 80~90 | 95~100 |
| performance (%) | | | |
| probe wear amount (%) | 100 | 90~95 | 95~100 |
| Probe cleaning efficiency | 100 | 85~90 | 95~100 |
| (%) | | | |

As shown in the data of [Experiment 4], if a further microstructural and mechanical efficacy analysis is conducted on the data of the aforementioned [Experimental example 4-1], [Experimental example 4-2], and [Experimental example 4-3], it could be clearly determined that [Experimental example 4-1] has the best overall performance. From the perspective of material and structural properties, the hollow glass microspheres adopted in [Experimental example 4-2] have an inorganic glass shell material with a relatively thick shell wall thickness (0.5 μm to 10 μm), which results in a higher true density and extremely high shell rigidity of the microspheres. When the probe contacts and penetrates at high speed, the relatively rigid and brittle glass shell cannot provide the flexible deformation space as that of organic polymers, resulting in a relative value of elastic rebound of only 80% to 90%. This means that its buffering capability for stress release and vibration damping is limited, which in turn subjects the probe to a greater rigid reaction force, and is reflected in the relatively poor relative values of probe wear and cleaning (reaching only 85% to 90%).

As shown in the data of [Experiment 3], when comparing [Experimental example 4-1] and [Experimental example 4-3], although both adopt organic polymer microspheres and possess similarly ultra-thin shell wall thicknesses (0.1 μm to 1.0 μm), the crosslinked PMMA microspheres of [Experimental example 4-3] are limited by the crosslinked network structure, and the extensibility and instantaneous compression flexibility of their polymer chain segments are still slightly inferior to those of the acrylonitrile-based copolymer of [Experimental example 4-1]. The acrylonitrile-based copolymer shell endows the microspheres with an extremely low true density (0.01 g/cm³ to 0.08 g/cm³) and superior compression fatigue resistance, enabling them to rapidly and non-destructively recover to the hollow state after withstanding repeated high-frequency, high-pressure impacts from the probe. Therefore, the hollow polymer microspheres of [Experimental example 4-1] are capable of providing the most stable and long-lasting elastic buffer stroke in the cleaning layer, maximally absorbing the downward impact force of the probe, achieving nearly zero-wear perfect protection, while simultaneously ensuring favorable dirt encapsulation and cleaning effects.

### Experiment 5

The purpose of [Experiment 5] is to adopt the experimental design philosophy similar to the Taguchi Methods, and through orthogonal arrays or analysis of variance, to identify the preferred adjustment directions and optimal parameter combinations for each parameter in the cleaning layer (e.g., internal structure, addition amount, overall hardness, etc.). The test methods or measurement approaches described in [Experiment 5] may be the same as or similar to those described above.

The material and fabrication method of [Experimental example 5] are essentially the same as those of the aforementioned [Experiment 1]. In [Experimental example 5], the content of hollow polymer microspheres is approximately 20 wt % (a moderate proportion), and the corresponding cleaning layer hardness is approximately 50 Shore A (moderate hardness). After the probe wear test, the wear amount of the probe is almost zero (the wear amount is marked as 0 μm, e.g., below the detection limit of the instrument or within the range of detection error). After the cleaning effect test, the contact resistance (CRES) performance is low and stable, and the overall yield rate is high. At the same time, the finished decontamination material exhibits almost no structural disintegration (e.g., no generation of corresponding particles or dust), demonstrating excellent structural stability.

[Comparative example 5-1] is a blank control group, containing no hollow polymer microspheres at all (addition amount is 0 wt %), and the corresponding cleaning layer hardness is approximately 50 Shore A. The probe wear amount after the probe wear test is as high as approximately 3.0 μm. The contact resistance after the cleaning effect test is high, and the yield rate is low. The finished product exhibits almost no structural disintegration (e.g., generation of corresponding particles or dust) phenomenon.

[Comparative example 5-2] is a structural control group, using “solid” microspheres of the same or similar material and size as the hollow polymer microspheres of [Experimental example 5], with the content also approximately 20 wt %, and the corresponding cleaning layer hardness is approximately 50 Shore A. The probe wear amount after the probe wear test is approximately 1.5 μm (partial wear). The contact resistance after the cleaning effect test is at a moderate level, and the yield rate is moderate. The finished product exhibits almost no structural disintegration phenomenon.

[Comparative example 5-3] is an addition amount control group, using the same hollow polymer microspheres as [Experimental example 5], but with the content significantly increased to greater than 350 wt % (excessively high), and the corresponding cleaning layer hardness surges to approximately 90 Shore A (excessively hard). The probe wear amount after the probe wear test is approximately 0.5 μm. However, the contact resistance after the cleaning effect test is extremely high, and the yield rate is extremely low (due to poor contact). Furthermore, the finished product exhibits severe structural disintegration phenomenon, generating a large amount of particles and dust, causing serious debris shedding.

[Comparative example 5-4] is a hardness control group, using the same hollow polymer microspheres as [Experimental example 5], with the content approximately 20 wt %, but with the formulation modified such that the corresponding cleaning layer hardness is less than 30 Shore A (excessively soft). The probe wear amount after the probe wear test is almost zero (the wear amount is below the detection limit). However, the contact resistance after the cleaning effect test is high, and the yield rate is low (due to insufficient cleaning). In addition, the surface of the finished product exhibits a phenomenon suspected to be colloidal residue, causing adhesion to the probe.

Further analysis of patent efficacy and technical characteristics based on the above test data could clearly confirm that, compared to each of the Comparative examples, [Experimental example 5] represents the optimal parameter combination.

First, by comparing [Experimental example 5] with [Comparative example 5-2], both have the same hardness and both contain 20 wt % of polymer microspheres added, wherein the sole difference in technical features resides in the “internal structure” of the microspheres (hollow structure versus solid structure). The solid microspheres of [Comparative example 5-2], although the material itself possesses a certain degree of softness, still caused 1.5 μm of physical wear to the probe due to the lack of yielding and cushioning space provided by an internal air chamber. In contrast, the hollow polymer microspheres of [Experimental example 5], through their corresponding hollow shock-absorbing mechanism, successfully reduced the probe wear to a protection level of almost “zero.”

Next, the effect of the addition amount on the overall structure is observed. Comparing [Experimental example 5] (20 wt %) with [Comparative example 5-1] (0 wt %) and [Comparative example 5-3] (>350 wt %), if no addition is made at all ([Comparative example 5-1]), the probe will be subjected to extremely large rigid frictional forces, resulting in severe wear of 3.0 μm, and the lack of microspheres to assist in adsorbing and carrying away contaminants causes the contact resistance to remain persistently high. Conversely, if the addition amount is excessively high ([Comparative example 5-3]), the excessively dense microspheres will disrupt the crosslinking continuity of the resin matrix, causing the cleaning layer to become brittle and the hardness to abnormally surge to 90 Shore A. When the probe presses down, the cleaning layer undergoes severe structural disintegration and debris shedding, completely losing its cleaning efficiency and causing secondary contamination.

Finally, the adaptability of the resin matrix hardness is discussed. Comparing [Experimental example 5] (50 Shore A) with [Comparative example 5-4] (<30 Shore A), both contain 20 wt % of hollow polymer microspheres. When the cleaning layer is excessively soft ([Comparative example 5-4]), although the probe exhibits almost no wear, the material lacks sufficient cohesion and resilient support force, causing the abrasive particles to be unable to produce effective cutting and scraping on the probe surface, resulting in a significant decrease in cleaning capability. At the same time, the excessively low crosslinking density is more likely to have caused the corresponding colloidal adhesion and residue problems.

As shown by the data of [Experiment 5], [Experimental example 5] appropriately controls the addition amount of hollow polymer microspheres within a moderate range (e.g., 20 wt %), and pairs it with a moderate resin matrix hardness (e.g., 50 Shore A), successfully achieving the optimal technical balance (trade-off) among the three physical properties that are often mutually constraining: “absorbing impact to achieve zero wear,” “ensuring high cleaning capability with low contact resistance,” and “maintaining high structural integrity (no debris shedding, no adhesive residue).”

In summary, the present disclosure provides a decontamination material applicable to the cleaning process of semiconductor test probes. The structure of the decontamination material mainly includes a support layer and a cleaning layer disposed thereon. The material of the cleaning layer not only includes a resin as a matrix, cleaning particles for assisting in adsorption and cushioning, and abrasive particles for providing physical cutting and decontamination capability, but also innovatively incorporates hollow polymer microspheres with appropriate physical specifications (e.g., corresponding particle size, extremely thin shell, and low true density) uniformly distributed therein. Through the elastic deformation and impact absorption capability of the hollow polymer microspheres, the decontamination material is able to provide excellent microscopic cushioning stroke and yielding space when the probe repeatedly and at high speed contacts and penetrates, thereby greatly reducing the scratch size and physical wear that the high hardness abrasive particles may cause to the probe tip. This porous composite structure design successfully achieves an optimized balance between “high-efficiency decontamination cutting” and “near-zero-wear probe protection.” It not only effectively removes residual contaminants on the probe surface and maintains long-term stable low contact resistance (CRES) and high test yield rate, but also, through controlling the addition amount and curing parameters, reduces or avoids brittle fracture, powder shedding, or structural disintegration of the cleaning layer when subjected to repeated high pressure, completely eliminating the risk of secondary contamination, thereby effectively extending the service life of the probe or probe card, and fully demonstrating the high utilization value and technical advancement of the present case in the high-end semiconductor testing industry.

### <Utility or Industrial Applicability>

The decontamination material and the manufacturing method thereof according to an embodiment of the present disclosure are suitable for being manufactured and applied industrially.

For example, the decontamination material of the present disclosure is particularly suitable for application in industries related to semiconductor testing or packaging testing, for cleaning probes, or for effectively removing stains and residues on the probes.

Through the design of the porous composite material of the present case, not only could the cleaning efficiency of the probe and the continuous test yield rate be improved, but the wear of the probe could also be significantly reduced and the service life of the probe card could be extended, and therefore the present case possesses appropriate and clear industrial applicability and commercial value in the field of semiconductor manufacturing and testing equipment.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A decontamination material, comprising:
a support layer; and
a cleaning layer disposed on the support layer, wherein the material of the cleaning layer comprises a resin, a plurality of cleaning particles dispersed in the resin, a plurality of abrasive particles dispersed in the resin, and a plurality of hollow polymer microspheres dispersed in the resin,
wherein a Mohs hardness of the cleaning particles is less than 7, and a Mohs hardness of the abrasive particles is greater than or equal to 7.

2. The decontamination material according to claim 1, wherein an average particle size of the hollow polymer microspheres is in a range from 10 micrometers to 200 micrometers.

3. The decontamination material according to claim 1, wherein the hollow polymer microspheres are present in an amount ranging from 5 wt % to 350 wt %, based on a total weight of the resin.

4. The decontamination material according to claim 1, wherein a shell material of the hollow polymer microspheres comprises at least one selected from the group consisting of an acrylonitrile-based copolymer, an acrylic-based copolymer, and an olefin-based polymer.

5. The decontamination material according to claim 1, wherein a true density of the hollow polymer microspheres is in a range from 0.01 g/cm³ to 0.08 g/cm³, and a shell wall thickness of the hollow polymer microspheres is in a range from 0.1 micrometers to 1.0 micrometers.

6. The decontamination material according to claim 1, wherein a Shore A hardness of the cleaning layer is in a range from 30 to 80.

7. The decontamination material according to claim 1, wherein an elastic modulus of the cleaning layer is in a range from 15 kg/cm² to 350 kg/cm².

8. The decontamination material according to claim 1, wherein a compression ratio of the cleaning layer is in a range from 23.9% to 57.4%.

9. The decontamination material of claim 1, wherein the resin has a weight average molecular weight ranging from 30,000 to 800,000, and the resin has a glass transition temperature ranging from −60° C. to −20° C.

10. The decontamination material of claim 1, wherein a particle size distribution of the cleaning particles is in a range from 0.05 micrometers to 30 micrometers, and a particle size distribution of the abrasive particles is in a range from 0.02 micrometers to 50 micrometers.

11. A method of manufacturing a decontamination material, comprising:
providing a support layer;
mixing a resin, a plurality of cleaning particles, a plurality of abrasive particles, and a plurality of hollow polymer microspheres to form a coating liquid, wherein a Mohs hardness of the cleaning particles is less than 7, and a Mohs hardness of the abrasive particles is greater than or equal to 7;
applying the coating liquid onto the support layer; and
curing the coating liquid to form a cleaning layer.

12. The method of claim 11, wherein curing the coating liquid comprises a preheating stage and a curing stage, wherein the temperature of the preheating stage is in a range from 40° C. to 120° C., and the temperature of the curing stage is in a range from 100° C. to 220° C.

13. A method of cleaning a probe, comprising:
providing the decontamination material according to claim 1;
applying pressure to cause a probe under test to penetrate the cleaning layer of the decontamination material, wherein the hollow polymer microspheres undergo elastic deformation to absorb an impact force during penetration of the probe under test; and
separating the probe under test from the cleaning layer to remove a substance therefrom, wherein at least a portion of the removed substance is encapsulated within the resin.

14. The method of claim 13, wherein the decontamination material is picked up and placed on a test device by a pick-up head of a pick-and-place device to clean a plurality of probes of the test device.

15. The method of claim 13, wherein the method is performed using operational parameters identical to those used for testing an electronic component, and wherein the method is performed in-situ or on-line.

16. The method of claim 13, wherein the probe under test is selected from the group consisting of a vertical probe, a cantilever probe, and a crown-type probe.
